(19) United States
(12) Patent Application Publication
(10) Pub. No.: US 2025/0207257 A1
(43) Pub. Date: Jun. 26, 2025

(54) CHAMBER ARRANGEMENTS INCLUDING BACKPRESSURE CONTROLLERS, SEMICONDUCTOR PROCESSING SYSTEMS INCLUDING CHAMBER ARRANGEMENTS, AND METHODS OF FORMING SEMICONDUCTOR STRUCTURES USING CHAMBER ARRANGEMENTS HAVING BACKPRESSURE CONTROLLERS

(71) Applicant: ASM IP Holding B.V., Almere (NL)

(72) Inventors: Saikat Banerjee, Tempe, AZ (US); Gregory Bartlett, Chandler, AZ (US); Joel Dickerson, Goodyear, AZ (US); Fan Gao, Chandler, AZ (US); Mingyang Ma, Phoenix, AZ (US); Prajwal Nagaraj, Tempe, AZ (US); Junwei Su, Chandler, AZ (US); Hongru Xu, Phoenix, AZ (US); Zack Zadecki, Peoria, AZ (US); Yue Zhao, Phoenix, AZ (US)

(21) Appl. No.: 19/000,826

(22) Filed: Dec. 24, 2024

Related U.S. Application Data
(60) Provisional application No. 63/614,681, filed on Dec. 26, 2023.

(51) Int. Cl. C23C 16/455; C23C 16/24; C23C 16/52

(52) U.S. Cl. CPC C23C 16/45557; C23C 16/24; C23C 16/52

(57) ABSTRACT

A chamber arrangement includes a chamber body, a mass flow controller (MFC) arrangement, and a bypass conduit. The MFC arrangement is coupled to the chamber body and includes a first inject MFC device and a second inject MFC device. The first inject MFC device is coupled to the chamber body. The second inject MFC device is coupled to the chamber body and is arranged fluidly in parallel with the first MFC device. The bypass conduit has a backpressure controller (BPC) arranged therealong, is arranged fluidly in parallel with the chamber body and the MFC arrangement, and one of the first inject MFC device and the second inject MFC device is operatively coupled to the BPC. Semiconductor processing systems and methods of forming semiconductor structures are also described.

### CROSS-REFERENCE TO RELATED APPLICATION(S)

This Application claims the benefit of U.S. Provisional Application 63/614,681 filed on Dec. 26, 2023, the entire contents of which are incorporated herein by reference.

### FIELD OF INVENTION

The present disclosure generally relates to forming semiconductor structures. More specifically, the present disclosure relates to controlling environment and flow conditions within chamber arrangements employed to form semiconductor structures.

### BACKGROUND OF THE DISCLOSURE

Semiconductor structures are commonly formed by depositing material layers onto substrates, generally by exposing the substrate to a material layer precursor while supported within a reactor and under conditions selected to cause a material layer precursor onto the substrate. In some semiconductor forming processes, variation within certain environmental conditions within the reactor can cause properties of a material layer forming the semiconductor structure vary. For example, pressure change within the reactor during semiconductor structure may cause properties within certain semiconductor structures to vary. Variation of flow rate of fluid introduced into the reactor during forming of the semiconductor structure may also cause properties of certain semiconductor structures to vary.

Such systems and methods of forming semiconductor structures have generally been considered suitable for their intended purpose. However, there remains a need in the art for improved chamber arrangements, semiconductor process systems having chamber arrangements, and related methods of forming semiconductor structures in chamber arrangements of semiconductor processing systems. The present disclosure provides a solution to this need.

### SUMMARY OF THE DISCLOSURE

A chamber arrangement is provided. The chamber arrangement includes a chamber body, a mass flow controller (MFC) arrangement, and a bypass conduit. The MFC arrangement is coupled to the chamber body and include a first MFC device and a second MFC device. The first inject MFC device is coupled to the chamber body, the second inject MFC device is coupled to the chamber body and arranged fluidly in parallel with the first inject MFC device, and the bypass conduit is arranged fluidly in parallel with the chamber body and the MFC arrangement. A backflow controller (BPC) is arranged along the bypass conduits and one of the first inject MFC device and the second inject MFC device is operatively coupled to the BPC.

In addition to one or more of the features described above, or as an alternative, further examples of the chamber arrangement may include that only one of the first inject MFC device and the second inject MFC device includes a pressure sensor.

In addition to one or more of the features described above, or as an alternative, further examples of the chamber arrangement may include an exhaust conduit connected to the chamber body and a supply conduit connected to the MFC arrangement. The MFC arrangement and the chamber body may fluidly couple the supply conduit in series with the exhaust conduit.

In addition to one or more of the features described above, or as an alternative, further examples of the chamber arrangement may include a process fluid diverter valve arranged along the supply conduit and a joint or union arranged along the exhaust conduit. The bypass conduit may couple the joint or union to the process fluid diverter valve.

In addition to one or more of the features described above, or as an alternative, further examples of the chamber arrangement may include that the process fluid diverter valve is a first process fluid diverter valve and that the chamber arrangement further includes a second process fluid diverter valve coupled to the supply conduit and therethrough to the MFC arrangement, a first process fluid source including a silicon-containing material layer precursor source coupled to the first process fluid diverter valve, and a second process fluid source including an etchant coupled to the second process fluid diverter valve.

In addition to one or more of the features described above, or as an alternative, further examples of the chamber arrangement may include a chamber pressure sensor arranged along the exhaust conduit and a pressure control valve. The pressure control valve may be arranged along the exhaust conduit. The pressure control valve may be coupled to the chamber body by the chamber pressure sensor.

In addition to one or more of the features described above, or as an alternative, further examples of the chamber arrangement may include that the first inject MFC device includes a housing supporting an inlet port, an outlet port, and a signal port; a flow rate sensor arranged within the housing and coupled to the inlet port; and a flow control valve arranged within the housing and coupling the flow rate sensor to the outlet port. A first inject MFC local controller may be arranged within the housing and coupled to the signal port to communicate a first inject MFC flow rate measurement to a system controller through the signal port and receive a first inject MFC flow rate setting through the signal port.

In addition to one or more of the features described above, or as an alternative, further examples of the chamber arrangement may include at least one of a jumper lead coupling the flow rate sensor to the signal port and a jumper module recorded on a memory of the first inject MFC local controller to relay the first inject MFC flow rate measurement to the system controller through the signal port and receive the first inject MFC flow rate setting from the system controller through the signal port.

In addition to one or more of the features described above, or as an alternative, further examples of the chamber arrangement may include that the second inject MFC device includes a housing supporting an inlet port, an outlet port, and a signal port; a pressure sensor arranged within the housing and coupled to the inlet port; a flow rate sensor arranged within the housing and coupled to the pressure sensor; and a flow control valve arranged within the housing and coupling the flow rate sensor to the outlet port. A second inject MFC local controller may be arranged within the housing and coupled to the signal port to communicate a supply pressure measurement and a first inject MFC flow rate measurement to a system controller through the signal port and receive a second inject MFC flow rate setting through the signal port.

In addition to one or more of the features described above, or as an alternative, further examples of the chamber arrangement may include at least one of a jumper lead coupling the flow rate sensor to the signal port and a jumper module recorded on a memory included in the second inject MFC local controller to relay the supply pressure measurement and the second inject MFC device flow rate measurement therethrough to the system controller and receive therethrough the second inject MFC flow rate setting from the system controller.

In addition to one or more of the features described above, or as an alternative, further examples of the chamber arrangement may include that the BPC includes a housing supporting an inlet port, an outlet port, and a signal port; a capacitive manometer arranged within the housing and coupled to the inlet port; a flow control valve arranged within the housing and coupling the capacitive manometer to the outlet port; and a BPC local controller arranged within the housing a coupled to the signal port. The BPC local controller may be responsive to instructions recorded on a memory to receive a backpressure setpoint from a system controller through the signal port, receive a backpressure measurement from the capacitive manometer, compare the backpressure measurement to the backpressure setpoint, and throttle backpressure within the bypass conduit when the backpressure measurement is greater than the backpressure setpoint by a predetermined backpressure differential value.

A semiconductor processing system is provided. The semiconductor processing system includes a chamber arrangement as described above wherein the MFC arrangement fluidly couples a supply conduit to an exhaust conduit; a process fluid diverter valve arranged along the supply conduit and a joint or union arranged along the exhaust conduit, wherein the bypass conduit couples the process fluid diverter valve to the joint or union; and a system controller. The system controller operatively couples the MFC arrangement to the BPC and is responsive to instructions recorded on a memory to receive a supply pressure measurement from the MFC arrangement acquired by one of the first inject MFC device and the second inject MFC device, receive a supply-to-bypass differential value, determine a backpressure setpoint using the supply pressure measurement and the supply-to-bypass differential value, and communicate the backpressure setpoint to the BPC to throttle backpressure within the bypass conduit using the supply pressure measurement.

In addition to one or more of the features described above, or as an alternative, further examples of the semiconductor processing system may include the instructions recorded on the memory further cause the controller to acquire a first inject MFC device flow rate measurement of the first process fluid as the first process fluid traverses the first inject MFC device, acquire a second inject MFC device flow rate measurement of the first process fluid as the first process fluid traverses the second inject MFC device, determine a first inject MFC device setpoint using the first inject MFC device flow rate measurement and the second inject MFC device flow rate measurement, determine a second inject MFC device setpoint using the first inject MFC device flow rate measurement and the second inject MFC device flow rate measurement, and communicate the first inject MFC device setpoint to the first inject MFC device and the second inject MFC device setpoint to the second MFC device.

In addition to one or more of the features described above, or as an alternative, further examples of the semiconductor processing system may include that determining the backpressure setpoint includes adding the supply-to-bypass differential value to the supply pressure measurement.

In addition to one or more of the features described above, or as an alternative, further examples of the semiconductor processing system may include that the supply-to-bypass differential value is zero.

In addition to one or more of the features described above, or as an alternative, further examples of the semiconductor processing system may include the supply-to-bypass differential value is a non-zero value.

A method of forming a semiconductor structure is provided. The method includes seating a substrate within the chamber body, flowing a first process fluid into the chamber body using the first inject MFC device and the second inject MFC device, forming a semiconductor structure on the substrate using the first process fluid, and throttling backpressure within a bypass conduit arranged fluidly in parallel with the MFC arrangement and the chamber arrangement with the BPC using a supply pressure measurement acquired by the one of the first inject MFC device and the second inject MFC device.

In addition to one or more of the features described above, or as an alternative, further examples of the method may include that the first process fluid includes a silicon-containing material layer precursor and that the second process fluid includes an etchant. The method may further include ceasing flow of the first process fluid to the chamber arrangement, switching flow of the second process fluid from the bypass conduit to the chamber arrangement, and removing a portion of a silicon-containing material layer deposited onto the substrate using the first process fluid using the second process fluid.

In addition to one or more of the features described above, or as an alternative, further examples of the method may include that the first inject MFC device does not include a pressure sensor. Throttling pressure within the bypass conduit may include comprises acquiring the supply pressure measurement using the second inject MFC device. determining a backpressure setpoint using the supply pressure measurement and a supply-to-pressure differential value, receiving the backpressure setpoint at the BPC and throttling backpressure within the bypass conduit according the backpressure setpoint during deposition of the material layer onto the substrate.

In addition to one or more of the features described above, or as an alternative, further examples of the method may include acquiring a first inject MFC device flow rate measurement of the first process fluid as the first process fluid traverses the first inject MFC device, acquiring a second inject MFC device flow rate measurement of the first process fluid as the first process fluid traverses the second inject MFC device, determining a first inject MFC device setpoint using the first inject MFC device flow rate measurement and the second inject MFC device flow rate measurement, determining a second inject MFC device setpoint using the first inject MFC device flow rate measurement and the second inject MFC device flow rate measurement, and communicating the first inject MFC device setpoint to the first inject MFC device and the second inject MFC device setpoint to the second inject MFC device.

A semiconductor structure is provided. The semiconductor device structure may be formed using the method of forming a semiconductor structure.

A semiconductor device is provided. The semiconductor device may include a semiconductor structure formed using the method of forming a semiconductor structure. The semiconductor device may have a gate-all-around architecture, a finned architecture, or a three-dimensional dynamic random access memory architecture.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system according to the present disclosure, showing a chamber arrangement and a backpressure controller connected fluidly in parallel with one another between a process fluid source and an exhaust source;

FIG. 2 is a schematic view of a portion of the semiconductor processing system of FIG. 1 including the backpressure controller and a system controller, showing elements of the backpressure controller and the system controller according to examples of the disclosure;

FIG. 3 is a schematic view of a portion of the semiconductor processing system of FIG. 1 including the process fluid source, showing first and second process fluid sources coupled to the chamber arrangement by process fluid diverter valves and mass flow control devices;

FIG. 4 is a schematic view of a portion of the semiconductor processing system of FIG, 1 including the chamber arrangement, showing an injection header coupled to a chamber body by an MFC arrangement and an injection flange according to an example of the disclosure;

FIG. 5 is a schematic view of a first inject MFC device of the MFC arrangement of FIG. 4, showing a first inject MFC device with no pressure sensor and a flow rate sensor directly coupled to an inlet port according to an example of the present disclosure;

FIG. 6 is a schematic view of a second inject MFC device of the MFC arrangement of FIG. 4, showing a second inject MFC device including a pressure sensor and a flow rate sensor, the pressure sensor coupling the flow rate sensor to an inlet port in an indirect coupling arrangement according to an example of the present disclosure;

FIG. 7 is a schematic view of a portion of the semiconductor processing system of FIG. 1, showing a pressure control valve and a joint or union coupling the chamber arrangement and the backpressure controller to the exhaust source according to an example of the disclosure;

FIG. 8 is a schematic view of the semiconductor processing system of FIG. 1 according to an example of the present disclosure, showing a deposition operation wherein a first process fluid is communicated to the chamber arrangement to deposit a material layer onto a substrate and a second process fluid is diverted to a bypass conduit;

FIG. 9 is a schematic view of the semiconductor processing system of FIG. 1 according to an example of the present disclosure, showing an etch operation wherein the first process fluid is diverted to the bypass conduit and a second process fluid is communicated to the chamber arrangement to remove material from the substrate and/or the material layer;

FIG. 10 is a block diagram of a method of forming a semiconductor structure in accordance with the present disclosure, showing operations of the method according to an illustrative and non-limiting example of the method;

FIGS. 11-15 are block diagram of operations of the method of forming a semiconductor structure of FIG. 10, showing operations for throttling backpressure within a bypass conduit and throttling mass flow rate of process fluid through an MFC arrangement during deposition and etch operation of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

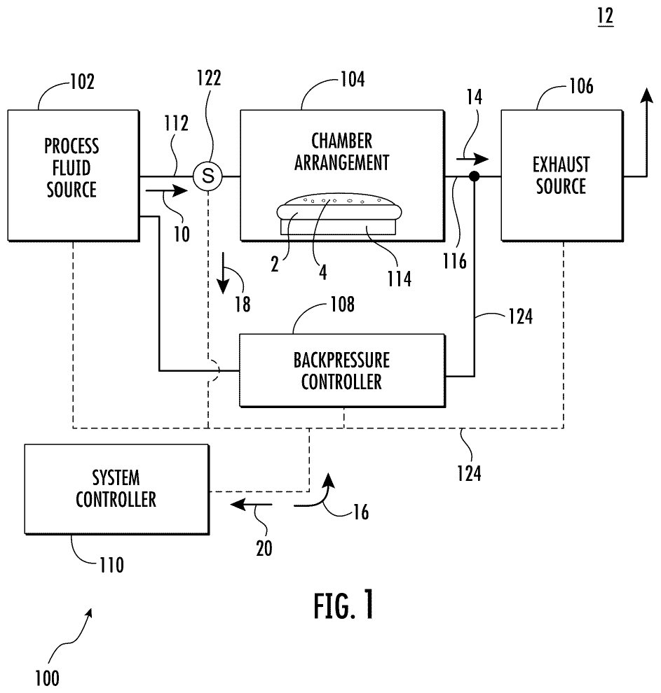

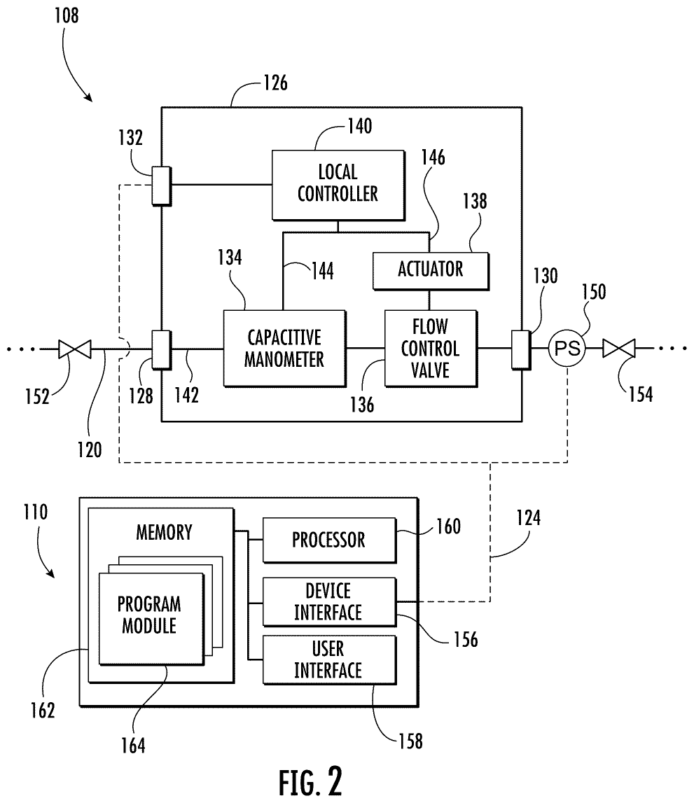

Reference will now be made to the drawings wherein like reference numerals identify similar structural features or aspects of the subject disclosure. For purposes of explanation and illustration, and not limitation, a partial view of an example of a chamber arrangement for a semiconductor processing system in accordance with the present disclosure is shown in FIG. 1 and is designated generally by reference character 104. Other examples of chamber arrangements, semiconductor processing systems including chamber arrangements, and methods of depositing material layers in semiconductor processing systems having chamber arrangements in accordance with the present disclosure, or aspects thereof, are provided in FIGS. 2-15, as will be described. The systems and methods of the present disclosure may be used to control fluid flow within semiconductor processing systems employed to form semiconductor structures, such as semiconductor structures having silicon-containing material layers deposited using epitaxial deposition techniques, though the present disclosure is not limited to any type of semiconductor structure or material layer having a specific composition in general.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including a 300-millimeter wafer. A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may be unpatterned, such as a so-called blanket-type substrate. As examples, substrates in the form of a powder may have applications for pharmaceutical manufacturing. A porous substrate may including one or more polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

Referring to FIG. 1, a semiconductor processing system 100 is shown. The semiconductor processing system 100 generally includes a process fluid source 102, a chamber arrangement 104, and an exhaust source 106. In the illustrated example the semiconductor processing system 100 also includes a backpressure controller 108 and a system controller 110. The process fluid source 102 is coupled to the chamber arrangement 104 by a supply conduit 112 and is configured to flow a process fluid 10 to the chamber arrangement 104. The chamber arrangement 104 includes a substrate support 114, is coupled to the exhaust source 106 by an exhaust conduit 116 and is configured to seat a substrate 2 therein and expose the substrate 2 to the process fluid 10 under conditions (e.g., temperature and pressure) that cause a material layer 4 to deposit onto the substrate 2. The exhaust source 106 is in communication with an external environment 12 outside of the semiconductor processing system 100 and is configured to communicate a flow residual material layer precursor and/or reaction products 14 issued by the chamber arrangement 104 to the external environment 12. In this respect the exhaust source 106 may include one or more vacuum pump and/or an abatement device, the one or more vacuum pump configured and adapted to maintain a reduced pressure within an interior 118 of the chamber arrangement 104.

The backpressure controller 108 is arranged along a bypass conduit 120 and couples the process fluid source 102 to the exhaust conduit 116. In this respect it is contemplated that the backpressure controller 108 be arranged in fluidly parallel with the chamber arrangement 104 between the process fluid source 102 and the exhaust source 106. In further respect, it is also contemplated that the backpressure controller 108 be configured to throttle backpressure within the bypass conduit 120 using a backpressure setpoint 16 received from the system controller 110. It is contemplated that the system controller 110 in turn be disposed in communication with the backpressure controller 108 and a supply pressure sensor 122, for example via a wired or wireless link 124, to determine the backpressure setpoint 16 using a supply pressure measurement 18 acquired by the supply pressure sensor 122 and a predetermined supply-to-bypass pressure differential value 20.

In certain examples, the predetermined supply-to-bypass pressure differential value 20 may be zero. As will be appreciated by those of skill in the art in view of the present disclosure, a predetermined supply-to-bypass pressure differential value of zero may limit pressure change that could otherwise be associated with introduction of flow of the process fluid 10 into the interior 118 of the chamber arrangement 104. Limiting pressure change within the interior 118 of the chamber arrangement 104 may in turn limit disturbance of a flow pattern 22 defined within the interior 118 of the chamber arrangement 104, potentially limiting (or eliminating) variation within material layer 4 otherwise associated with introduction of flow of the process fluid 10 into the interior 118 of the chamber arrangement 104. In accordance with certain examples of the present disclosure, the predetermined supply-to-bypass pressure differential value 20 may be a non-zero value, for example a positive or negative value. As will also be appreciated by those of skill in the art in view of the present disclosure, predetermined supply-to-bypass pressure differential values may impart potentially desirably properties into the material layer 4, such as material layer edge thickness variation (e.g., using a positive predetermined supply-to-bypass pressure differential value selected to limit residency of the process at the edge of the substrate 2), or dopant within-thickness variation (e.g., using a negative predetermined supply-to-bypass pressure differential value selected in cause the process fluid 10 to linger at the edge of the substrate 2 upon introduction into the interior 118 of the chamber arrangement 104). As will be further appreciated by those of skill in the art in view of the present disclosure, other process tuning effects may be imparted into processing of the substrate 2 within the chamber arrangement 104 using the predetermined supply-to-bypass pressure differential value 20 and remain within the scope of the present disclosure.

With reference to FIG. 2, the backpressure controller 108 and the system controller 110 are shown according to examples of the present disclosure. In the illustrated example the backpressure controller 108 includes a housing 126, an inlet port 128, an outlet port 130, and a signal port 132. As shown and described herein the backpressure controller 108 also includes a capacitive manometer 134, a flow control valve 136, an actuator 138, and a BPC local controller 140. The housing 126 supports the inlet port 128, the outlet port 130, and the signal port 132. The inlet port 128 couples the outlet port 130 to the process fluid source 102 (shown in FIG. 1). The outlet port 130 is coupled to the inlet port 128 by a fluid channel 142 extending through the housing 126 and couples the inlet port 128 to the exhaust source 106 (shown in FIG. 1). The signal port 132 provides communication between the BPC local controller 140 and the system controller 110 and in this respect may be coupled to the system controller 110 by the wired or wireless link 124. It is contemplated that the BPC local controller 140 be arranged within an interior of the housing 126, be disposed in communication with the capacitive manometer 134 to receive a backpressure measurement 24 from the capacitive manometer 134 indicative of backpressure within the bypass conduit 120. It is also contemplated that the BPC local controller 140 be operatively coupled to the flow control valve 136, for example via the actuator 138.

The capacitive manometer 134 is arranged along the fluid channel 142 and couples the flow control valve 136 to the inlet port 128. The capacitive manometer 134 is further coupled to the BPC local controller 140 by a manometer lead 144 and is configured to acquire the backpressure measurement 24. The flow control valve 136 is also arranged along the fluid channel 142 and fluidly couples the capacitive manometer 134 to the outlet port 130. It is contemplated that the flow control valve 136 be configured to throttle backpressure within the bypass conduit 120, for example by increasing or decreasing an effective flow area within the bypass conduit 120. Throttling may be accomplished by the actuator 138, which may be mechanically coupled to the flow control valve 136, for example through a link or linkage, and which may in turn be coupled to the BPC local controller 140 by an actuator lead 146 to receive drive signal 148 from the BPC local controller 140. Examples of suitable capacitive manometers include Baratron® manometers, available from MKS Instruments Inc. of Hatfield, Pennsylvania.

The BPC local controller 140 may include a BPC device interface, a BPC processor, and a BPC memory. The BPC device interface may couple the BPC processor to the signal port 132, the manometer lead 144, and the actuator lead 146. The BPC memory includes a non-transitory machine-readable medium having a plurality of program modules recorded on the BPC memory that, when read by the BPC processor, cause the BPC processor to execute certain operations to control backpressure within the bypass conduit 120. Among the operations are operations to (a) receive the backpressure setpoint 16 from the system controller 110, (b) receive the backpressure measurement 24 from the capacitive manometer 134, and (c) throttle the effective flow area defined by the flow control valve 136 when the backpressure measurement 24 differs from the backpressure setpoint 16 by more than a predetermined differential, such as using a lookup table recorded on the BPC memory. As will be appreciated by those of skill in the art in view of the present disclosure, the aforementioned operations enable the BPC 108 to throttle backpressure within the bypass conduit 120 dynamically, for example according to more than one backpressure setpoint during deposition of the material layer 4 (shown in FIG. 1) onto the substrate 2 (shown in FIG. 1). In this respect the BPC 108 may maintain a first backpressure within the bypass conduit 120 during a deposition step of a process recipe and maintain a second backpressure within the bypass conduit 120 during an etch step of the process recipe, such as during deposition of the material layer 4 using a cyclic deposition/tech technique.

It is contemplated that the chamber arrangement 104 (shown in FIG. 1) may include a pressure switch 150, for example to protect the BPC 108 from overpressure and/or backstreaming of fluid from the exhaust conduit 116 to the supply conduit 112 via the bypass conduit 120. The pressure switch 150 may be arranged along the bypass conduit 120 and configured to fluidly separate the process fluid source 102 (shown in FIG. 1) from the exhaust source 106 (shown in FIG. 1) when pressure within the bypass conduit 120 exceeds a predetermined pressure, for example a pressure that may cause the BPC 108 to require calibration. In certain examples, the pressure switch 150 may couple the BPC 108 to the process fluid source 102, In accordance with certain examples, the pressure switch 150 may couple the BPC 108 to the exhaust source 106. It is also contemplated that that pressure switch 150 may be one of a pair of backpressure switches coupling the BPC to both the process fluid source 102 and the exhaust source 106. In accordance with certain examples, the pressure switch 150 may cooperate with an interlock circuit. As will be appreciated by those of skill in the art in view of the present disclosure, protecting the BPC 108 with the pressure switch 150 may improve reliability of the semiconductor processing system 100 (shown in FIG. 1), for example by limiting risk that exposure to BPC 108 to pressure outside of an expected operating of range require recalibration of the BPC 108, such as during a maintenance event during which the chamber arrangement 104 (shown in FIG. 1) is purged with a relatively high pressure inert gas.

It is also contemplated that the chamber arrangement 104 (shown in FIG. 1) may include a first shutoff valve 152 and a second shutoff valve 154. The first shutoff valve 152 may couple the BPC 108 to the process fluid source 102 (shown in FIG. 1) and be configured to fluidly separate the BPC 108 from the process fluid source 102. The second shutoff valve 154 may be couple the BPC 108 to the exhaust source 106 and be configured to fluid separate the BPC 108 from the exhaust source 106. In certain examples, pressure switch 150 may fluidly couple the BPC 108 to the first shutoff valve 152. In accordance with certain examples, the second shutoff valve 154 may fluidly couple the pressure switch 150 to the exhaust source 106 (shown in FIG. 1). It is contemplated that, in certain examples of the present disclosure, either (or both) the first shutoff valve 152 and the second shutoff valve 154 may include a manual or a solenoid actuator, facilitating operation of the first shutoff valve 152 and the second shutoff valve 154 in settings where administrative lockout/tagout are employed as well as in settings where remote maintenance is employed. As will be appreciated by those of skill in the art in view of the present disclosure, the first shutoff valve 152 and the second shutoff valve 154 enable fluidly separating the pressure switch 150 from the process fluid source 102 and the exhaust source 106, limiting nuisance tripping of the pressure switch 150 during maintenance events where relatively high pressure fluids are introduced into the chamber events.

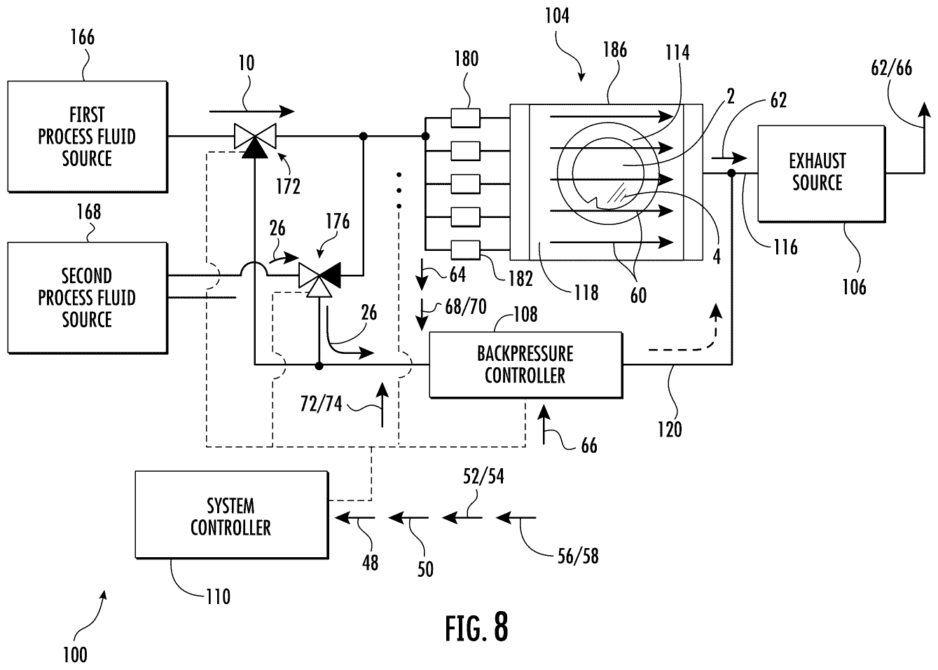

In the illustrated example the system controller 110 includes a device interface 156, a user interface 158, a processor 160, and a memory 162. The device interface 156 couples the processor 160 to the wired or wireless link 124 and therethrough to the supply pressure sensor 122 and the BPC 108. The processor 160 is operatively connected to the user interface 158 to receive user input and/or provide user output therethrough and is disposed in communication with the memory 162. The memory 162 includes a non-transitory machine-readable medium having a plurality of program modules 164 recorded thereon that, when read by the processor 160, cause the processor 160 to execute certain operations. Among the operations are operations a material layer deposition method 200 (shown in FIG. 8), as will be described. Although shown and described herein as having a specific architecture it is to be understood and appreciated that the system controller 110 may have different architectures in other examples, e.g., a distributed computing architecture, and remain within the scope of the present disclosure.

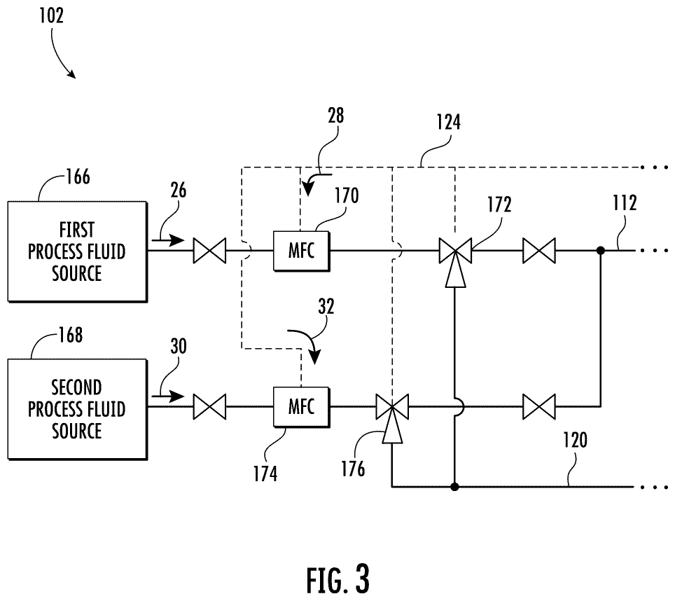

With reference to FIG. 3, the process fluid source 102 is shown. In the illustrated example the process fluid source 102 includes a first process fluid source 166 and a second process fluid source 168. The first process fluid source 166 includes a first process fluid 10 and is configured to communicate a flow of the first process fluid 10 to a first process fluid mass flow controller (MFC) device 170 and therethrough to a first process fluid diverter valve 172 according to a first process fluid mass flow setpoint 28. The first process fluid MFC device 170 couples the first process fluid source 166 to the first process fluid diverter valve 172 and may be disposed in communication with the system controller 110, for example via the wired or wireless link 124, to receive therefrom the first process fluid mass flow setpoint 28. The first process fluid diverter valve 172 in turn couples the first process fluid MFC device 170 to the supply conduit 112, and therethrough to the chamber arrangement 104 (shown in FIG. 1), and the bypass conduit 120. It is contemplated that the first process fluid diverter valve 172 be operably associated with the system controller 110, for example via the wired or wireless link 124, to direct flow of the first process fluid 10 between the supply conduit 112 and the bypass conduit 120. As will be appreciated by those of skill in the art in view of the present disclosure, switching flow of the first process fluid 10 between the supply conduit 112 and the bypass conduit 120 may limit stabilization time otherwise required for reliable mass flow the first process fluid 10 communicated by the first process fluid MFC device 170, increasing throughput of the semiconductor processing system 100 (shown in FIG. 1). It is contemplated that one or more isolation valves may fluidly couple the first process fluid source 166 to the supply conduit 112, for example, facilitate maintenance of the semiconductor processing system 100 (shown in FIG. 1).

The second process fluid source 168 includes a second process fluid 26 and is configured to communicate a flow of the second process fluid 26 to a second process fluid MFC device 174 and therethrough to a second process fluid diverter valve 176 according to a second process fluid mass flow setpoint 32. The second process fluid MFC device 174 couples the second process fluid source 168 to the second process fluid diverter valve 176. The second process fluid MFC device 174 may also be disposed in communication with the system controller 110, for example via the wired or wireless link 124, to flow the second process fluid 26 to the second process fluid diverter valve 176 according to a second process fluid mass flow setpoint 32. The second process fluid diverter valve 176 may in turn couple the second process fluid MFC device 174 to the supply conduit 112 and therethrough to the chamber arrangement 104 (shown in FIG. 1) as well as the bypass conduit 120. It is contemplated that the second process fluid diverter valve 176 may also be operably associated with the system controller 110, for example via the wired or wireless link 124, to switch flow of the second process fluid 26 between the supply conduit 112 and the bypass conduit 120. As will be appreciated by those of skill in the art in view of the present disclosure, diverting flow of the second process fluid 26 between the supply conduit 112 and the bypass conduit 120 may also limit stabilization time otherwise required for reliable mass flow the second process fluid 26 communicated by the second process fluid MFC device 174, also increasing throughput of the semiconductor processing system 100 (shown in FIG. 1). It is further contemplated that one or more isolation valves may fluidly couple the second process fluid source 168 to the supply conduit 112, also to facilitate maintenance of the semiconductor processing system 100 (shown in FIG. 1).

In certain examples the first process fluid 10 may be a material layer precursor. In this respect it is contemplated that the first process fluid 10 may include one or more silicon-containing material layer precursor. Examples of suitable silicon-containing material layer precursors include non-halogenated silicon-containing material layer precursors, such as silane (SiH₄) and disilane (Si₂H₆), and halogenated silicon-containing material layer precursors such as dichlorosilane (H₂SiCl₂) and trichlorosilane (HCl₃Si). In accordance with certain examples, the second process fluid 26 may include an etchant, such as hydrochloric acid (HCl) or chlorine (Cl₂) gas by way of non-limiting example.

It is contemplated that the first process fluid 10 may include an alloying constituent, such as a germanium-containing material layer precursor like germane (GeH₄), or a dopant-containing material layer precursor like arsine (AsH₃) or phosphine (PH₃). It is also contemplated that either (or both) the first process fluid 10 and the second process fluid 26 may include a carrier/diluent fluid. Examples of suitable carrier/diluent fluids include hydrogen (H₂) gas, as nitrogen (N₂) gas, noble gases like argon (Ar) gas and krypton (Kr) gas as well as mixtures including the aforementioned gases. Although shown and described herein as having two (2) process fluid sources it is to be understood and appreciated that the process fluid source 102 may include different numbers of process fluid sources in other examples and remain within the scope of the present disclosure.

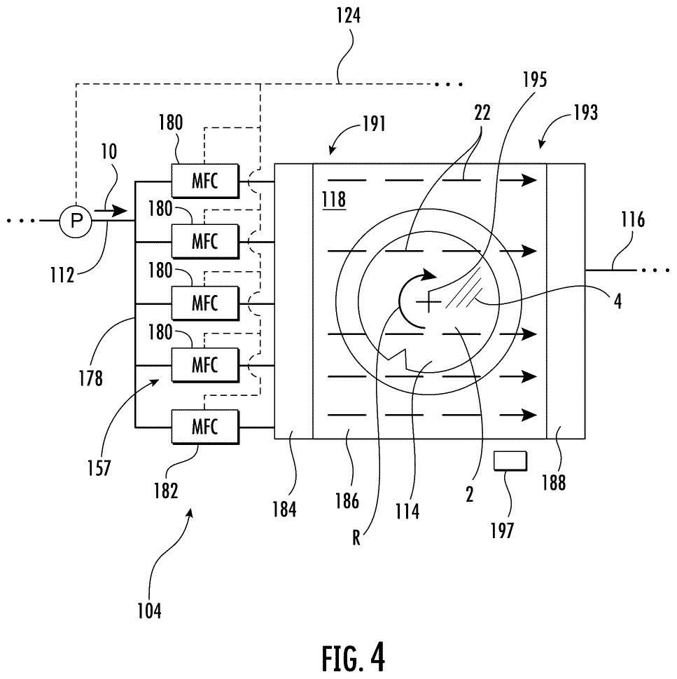

With reference to FIG. 4, the chamber arrangement 104 is shown. In the illustrated example the chamber arrangement 104 includes an inject header 178, a first inject MFC device 180, a second inject MFC device 182, an injection flange 184, a chamber body 186, and an exhaust flange 188. The chamber body 186 extends between an inject end 191 and a longitudinally opposite exhaust end 193 and may be formed from a ceramic material, such as quartz. It is contemplated that the substrate support 114 be supported within the interior 118 of the chamber arrangement 104 for rotation R about a rotation axis 195 during deposition of the material layer 4 onto the substrate 2. It is also contemplated that the exhaust flange 188 abut the exhaust end 193 of the chamber body 186 and couple the chamber body 186 to the exhaust conduit 116, that the injection flange 184 abut the inject end 191 of the chamber body 186 and couple the chamber body 186 to the supply conduit 112, and that the chamber body 186 be configured to flow the process fluid 10 in a flow pattern 22 with a lateral flow distribution determined by lateral spacing and process fluid mass flow rates determined by the first inject MFC device 180 and the second inject MFC device 182. It is contemplated that the chamber arrangement 104 may be as shown and described in U.S. Pat. No. 7,897,491 to Bauer et al., issued on Mar. 1, 2011, the contents of which are incorporated herein by reference in their entirety.

The first inject MFC device 180 and the second inject MFC device 182 couple the inject header 178 to the injection flange 184 and therethrough to the chamber body 186. The inject header 178 in turn couples the supply conduit 112 to the first inject MFC device 180 and the second inject MFC device 182, and therethrough the process fluid source 102 (shown in FIG. 1) to the interior 118 of the chamber body 186. It is contemplated that the second inject MFC device 182 be arranged fluidly in parallel with the first inject MFC device 180. It is also contemplated that the first inject MFC device 180 and the second inject MFC device 182 each be configured to flow a predetermined ratio of the process fluid 10 received at the inject header 178 according to a mass flow rate measurements acquired by the first inject MFC device 180 and the second inject MFC device 182, the mass flow rates aggregated externally of the first inject MFC device 180 and the second inject MFC device 182, and the aggregated mass flow rates employed to update mass flow rate setpoints communicated to the first inject MFC device 180 and the second inject MFC device 182. In this respect it is contemplated that the first inject MFC device 180 and the second inject MFC device 182 be disposed in communication with the system controller 110, for example via the wired or wireless link 124. In the illustrated example the first inject MFC device 180 is one of four (4) first inject MFC devices that cooperate with a singular second inject MFC device, e.g., the second inject MFC device 182. As will be appreciated by those of skill in the art in view of the present disclosure, the chamber arrangement 104 may include fewer or additional first inject MFC devices and second inject MFC devices and remain within the scope of the present disclosure.

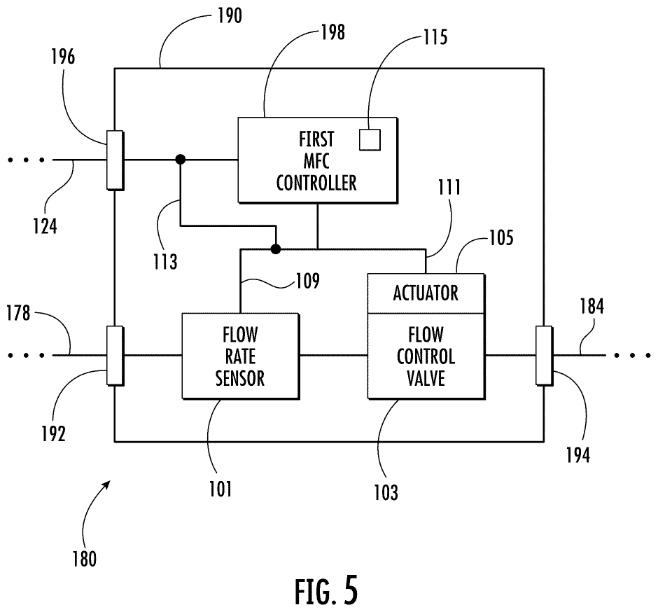

With reference to FIG. 5, the first inject MFC device 180 is shown. In the illustrated example the first inject MFC device 180 includes a housing 190, an inlet port 192, an outlet port 194, and a signal port 196. As shown and described herein the first inject MFC device 180 also includes a first inject MFC local controller 198, a flow rate sensor 101, a flow rate control valve 103, and an actuator 105. Although shown and described herein an including certain elements, it is to be understood and appreciated that the first inject MFC device 180 may include additional elements and/or omit elements shown and described herein and remain within the scope of the present disclosure. Examples of suitable first inject MFC devices include GF125 Series MFC devices available from Brooks Instrument LLC of Hatfield, Pennsylvania.

The housing 190 supports the inlet port 192, the outlet port 194, and the signal port 196. The inlet port 192 is connected to the inject header 178 (shown in FIG. 4) and fluidly couples the inject header 178 to the outlet port 194 of the first inject MFC device 180 through the flow rate sensor 101 and the flow rate control valve 103. The outlet port 194 of the first inject MFC device 180 is connected to the injection flange 184 (shown in FIG. 4) and fluidly couples the inject header 178 to the injection flange 184 through the inlet port 192 and the outlet port 194 of the first inject MFC device 180. The signal port 196 is connected to the wired or wireless link 124, couples the first inject MFC local controller 198 to the wired or wireless link 124 and therethrough to the system controller 110. The first inject MFC local controller 198 may be similar to the BPC local controller 140 (shown in FIG. 2) and additionally configured to relay a first MFC flow rate measurement acquired by the flow rate sensor 101 to the system controller 110. It is also contemplated that the first inject MFC local controller 198 be configured to relay a first MFC device flow rate setting 36 received from the system controller 110 to the actuator 105, the actuator 105 thereby throttling an effective flow area defined by the flow rate control valve 103 through the first inject MFC device 180 according to the first MFC device flow rate setting 36.

The flow rate sensor 101 and the flow rate control valve 103 are arranged fluidly in series within the housing 190 along a flow channel 107 and couple the inlet port 192 of the first inject MFC device 180 to the outlet port 194 of the first inject MFC device 180. In this respect the flow rate sensor 101 couples the inlet port 192 to the flow rate control valve 103, is configured to acquire the first inject MFC device flow rate measurement 34, and is connected to the first inject MFC local controller 198 by a flow rate sensor lead 109 to provide the first inject MFC device flow rate measurement 34 to the first inject MFC local controller 198. In further respect, the flow rate control valve 103 couples the flow rate sensor 101 to the outlet port 194 and is operably associated with the system controller 110 (shown in FIG. 1) via the actuator 105 and an actuator lead 111. In certain examples the first inject MFC local controller 198 may be configured to throttle the effective flow area defined by the flow rate control valve 103 according to the first inject MFC device flow rate measurement 34. In such examples such functionality may be bypassed, for example via a jumper lead 113 and/or a jumper module 115 resident on the first inject MFC local controller 198, the effective flow area defined by the flow rate control valve 103 thereby control in real time ex-situ according to a total flow ratio determination made by the system controller 110 using flow rate measurements acquired by first inject MFC device 180 and the second inject MFC device 182 (shown in FIG. 4).

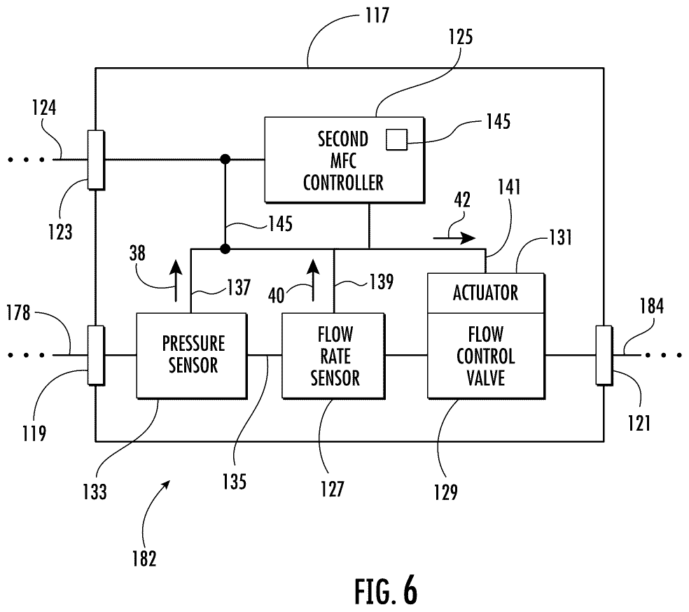

With reference to FIG. 6, the second inject MFC device 182 is shown. In the illustrated example the second inject MFC device 182 is similar to the first inject MFC device 180 and includes a housing 117, an inlet port 119, an outlet port 121, and a signal port 123. The second inject MFC device 182 also includes a second inject MFC local controller 125, a flow rate sensor 127, a flow rate control valve 129, and an actuator 131. As shown and described herein the second inject MFC device 182 additionally includes a local (i.e., contained within the second inject MFC device 182) pressure sensor 133. Advantageously, inclusion of the pressure sensor 133 may simplify the semiconductor processing system 100 (shown in FIG. 1), for example by eliminating the need to include the supply pressure sensor 122 (shown in FIG. 1) along the supply conduit 112. Although shown and described herein an including certain elements it is to be understood and appreciated that the second inject MFC device 182 may include additional elements, and/or omit elements shown and described herein, and remain within the scope of the present disclosure. Examples of suitable first inject MFC devices include GF126 Series MFC devices, also available from Brooks Instrument LLC of Hatfield, Pennsylvania.

The housing 117 of the second inject MFC device 182 supports the inlet port 119, the outlet port 121, and the signal port 123. The inlet port 119 is connected to the inject header 178 (shown in FIG. 4) and fluidly couples the inject header 178 to the outlet port 121 of the second inject MFC device 182 through the flow rate sensor 127 and the flow rate control valve 129 of the second inject MFC device 182. The outlet port 121 of the second inject MFC device 182 is connected to the injection flange 184 (shown in FIG. 4) of the chamber arrangement 104 (shown in FIG. 4) and fluidly couples the inject header 178 to the injection flange 184 through the inlet port 119 and the outlet port 121 of the second inject MFC device 182. The signal port 123 is connected to the wired or wireless link 124 and couples the second inject MFC local controller 125 to the wired or wireless link 124 and therethrough to the system controller 110 (shown in FIG. 1). The second inject MFC local controller 125 may also be similar to the BPC local controller 140 (shown in FIG. 2) and additionally be configured to relay an inject pressure measurement 38 and a second inject MFC flow rate measurement 40 acquired by the pressure sensor 133 and the flow rate sensor 127, respectively, to the system controller 110. It is also contemplated that the second inject MFC local controller 125 be configured to relay a second MFC device flow rate setting 42 received from the system controller 110 to the actuator 131, the actuator 131 thereby throttling an effective flow area through the second inject MFC device 182 according to the second MFC device flow rate setting 42.

The pressure sensor 133 and the flow rate sensor 127 are supported within the housing 117, are connected fluidly in series with one another between the inlet port 119 and the flow rate control valve 129. In this respect it is contemplated that the pressure sensor 133 and the flow rate sensor 127 be arranged along a flow channel 135 fluidly coupling the inlet port 119 to the outlet port 121 of the second inject MFC device 182, the pressure sensor 133 coupling the flow rate sensor 127 to the inlet port 119, the flow rate sensor 127 coupling the flow rate control valve 129 to the pressure sensor 133, and the flow rate control valve 129 coupling the outlet port 121 to the flow rate sensor 127. It is further contemplated that pressure sensor 133 be configured to acquire the inject pressure measurement 38 from fluid traversing the flow channel 135 and provide the inject pressure measurement 38 to the system controller 110 (shown in FIG. 1) via the signal port 123, that the flow rate sensor 127 be configured to provide the second inject MFC flow rate measurement 40 to the system controller 110 via the signal port 123, and that the flow rate control valve 129 be configured to throttle an effective flow area through the second inject MFC device 182 via a second MFC device flow rate setting 42 received via the signal port 123. In this respect the pressure sensor 133 may be coupled to the second inject MFC local controller 125 by a pressure sensor lead 137, the flow rate control valve 129 may be coupled to the second inject MFC local controller 125 controller by a flow control valve lead 139, and the actuator 131 may be coupled to the second inject MFC local controller 125 by an actuator lead 141.

In certain examples, the second inject MFC local controller 125 may be configured to throttle the effective flow area defined by the flow rate control valve 129 by comparing the second inject MFC flow rate measurement 40 to a predetermined mass flow rate setting. In such examples this functionality may be bypassed, for example via a jumper lead 143 and/or a jumper module 145 resident on a memory included in the second inject MFC local controller 125, backpressure within the bypass conduit 120 controlled in real-time according to the second MFC device flow rate setting 42 received from the system controller 110. In this respect it is contemplated that the system controller 110 also be configured to determine the second MFC device flow rate setting 42 according total flow through each of the inject MFC devices, e.g., the first inject MFC device 180 (shown in FIG. 4) and the second inject MFC device 182, using the first inject MFC device flow rate measurement 34 (shown in FIG. 5) and the second inject MFC flow rate measurement 40. As will be appreciated by those of skill in the art in view of the present disclosure, controlling mass flow of fluid through the second inject MFC device 182 on the basis of total flow through the first inject MFC device 180 and the second inject MFC device 182 may improve accuracy of fluid distribution into the flow pattern 22 (shown in FIG. 2) defined within the chamber body 186, improving control over properties of the material layer 4 deposited onto the substrate 2.

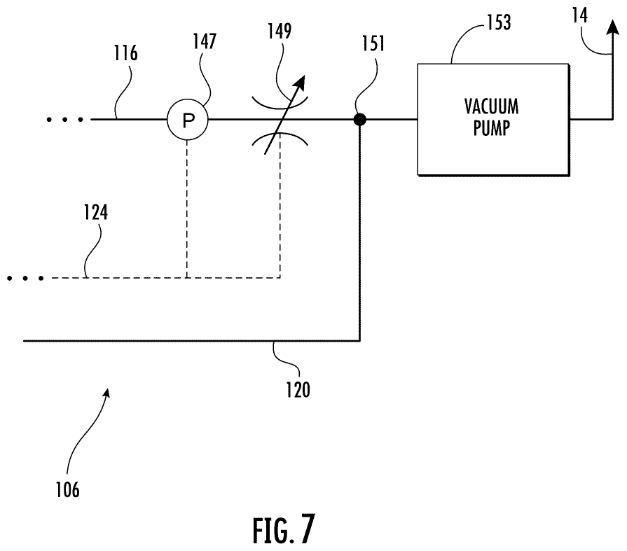

With reference to FIG. 7, the exhaust source 106 is shown. In the illustrated example the exhaust source 106 includes a chamber pressure sensor 147, a pressure control valve 149, a joint or union 151, and a vacuum pump 153. The chamber pressure sensor 147 is arranged along the exhaust conduit 116, couples the pressure control valve 149 to the chamber body 186 (shown in FIG. 4) and is configured to provide a chamber pressure measurement 44 to the system controller 110 (shown in FIG. 1), for example via the wired or wireless link 124. The pressure control valve 149 is also arranged along the exhaust conduit 116 and the joint or union 151 to the chamber pressure sensor 147. The joint or union 151 in turn couples the bypass conduit 120 to the exhaust conduit 116 and the vacuum pump 153 to the chamber pressure sensor 147 (and is coupled by the bypass conduit 120 to the first process fluid source 166 and the second process fluid source 168), and is configured to control pressure within the interior 118 (shown in FIG. 4) of the chamber body 186 for example by throttling an effective flow area defined by the pressure control valve 149 and along the exhaust conduit 116. In this respect it is contemplated that the pressure control valve 149 be operatively associated with the system controller 110, for example via the wired or wireless link 124, to control pressure within the chamber body 186 according to a chamber pressure value setting 46 received from the system controller 110 via the wired or wireless link 124. In certain examples one or more of the chamber pressure sensor 147, the pressure control valve 149, and the joint or union 151 may be included in a foreline assembly coupling the exhaust conduit 116 to the chamber body 186. As will be appreciated by those of skill in the art in view of the present disclosure, arranging the joint or union 151 fluidly between the vacuum pump 153 and the pressure control valve 149 and/or the chamber pressure sensor 147 may limit exposure of the pressure control valve 149 and/or the chamber pressure sensor 147 to process fluid flowing the vacuum pump, increasing availability of the semiconductor processing system 100.

It is contemplated that the system controller 110 (shown in FIG. 1) be cooperate with the chamber pressure sensor 147 and the pressure control valve 149 to control pressure within interior 118 (shown in FIG. 4) of the chamber body 186 (shown in FIG. 4) during deposition of the material layer 4 (shown in FIG. 1) onto the substrate 2 (shown in FIG. 1). In this respect it is contemplated that the system controller 110 may be responsive to instructions recorded in a plurality of program modules recorded on a memory, e.g., the plurality of program modules 164 (shown in FIG. 2) recorded on the memory 162 (shown in FIG. 2), to (a) receive a chamber pressure value, for example via a process recipe received at the user interface 158 (shown in FIG. 2); (b) receive the chamber pressure measurement 44; (c) compare the chamber pressure measurement 44 to the chamber pressure value; and (d) determine, and thereafter provide, the chamber pressure value setting 46 to the pressure control valve 149 when the chamber pressure measurement 44 differs from the chamber pressure value by more than a predetermine amount. In certain examples, chamber pressure control may be accomplished independently of process fluid flow rate adjustments and/or backpressure control within the bypass conduit 120 (shown in FIG. 1). As will be appreciated by those of skill in the art in view of the present disclosure, this enables the feedback loops to be ordered in time according to magnitude, promoting stability of flow pattern 22 (shown in FIG. 4) within the interior 118 of the chamber body 186 during deposition of the material layer 4 onto the substrate 2.

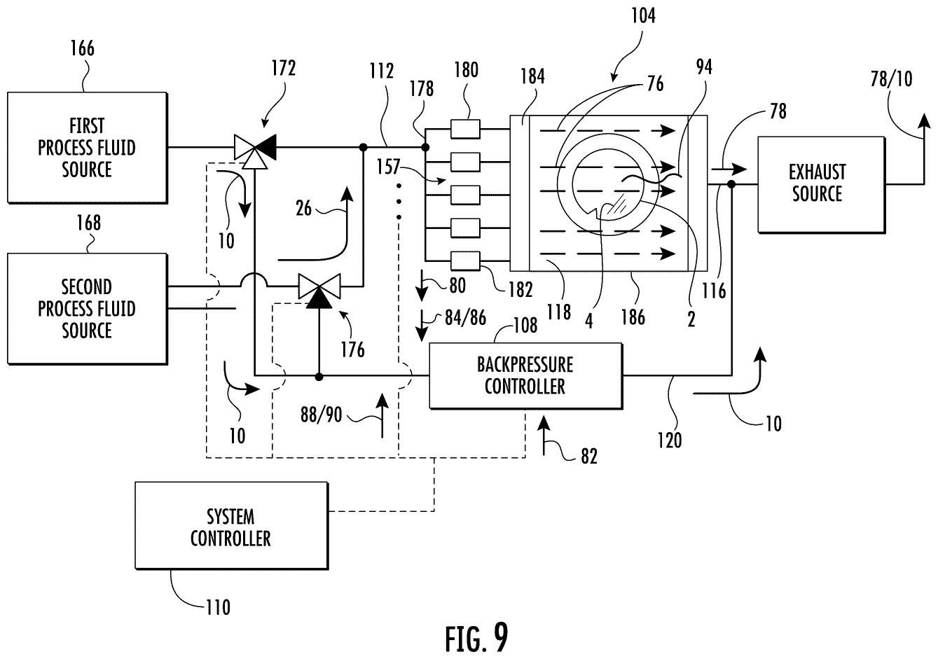

With reference to FIGS. 8 and 9, the BPC 108 is shown controlling backpressure with the bypass conduit 120 and process fluid flows into the chamber arrangement 104 during formation of the material layer 4 onto the substrate 2 using a deposition operation I (shown in FIG. 8) and an etch operation II (shown in FIG. 9). As shown in FIG. 8, formation of the material layer 4 onto the substrate 2 begins when the system controller 110 receives one or more supply-to-bypass pressure differential values, e.g., a deposition supply-to-bypass pressure differential value 48 for controlling backpressure during the deposition operation I and an etch supply-to-bypass pressure differential value 50 for controller backpressure during the deposition operation II. In certain examples, either (or both) the deposition supply-to-bypass pressure differential value 48 and the etch supply-to-bypass pressure differential value 50 may be zero. In accordance with certain examples, either (or both) the deposition supply-to-bypass pressure differential value 48 and the etch supply-to-bypass pressure differential value 50 may be a non-zero value, such as a positive and/or a negative value. It is also contemplated that, in accordance with certain examples, the system controller 110 may further receive a deposition operation first inject MFC device flow ratio target 52 and deposition operation second inject MFC device flow ratio target 54 for use during the deposition operation I, and an etch operation first inject MFC device flow ratio target 56 and an etch operation second inject MFC device flow ratio target 58 for use during the etch operation II. The aforementioned values may be received as parameters associated with a process recipe, such as a process recipe string received from a factory host computer via the user interface 158 (shown in FIG. 2) of the system controller 110 (shown in FIG. 1).

The deposition operation I may include seating the substrate within the interior 118 of the chamber body 186 and on the substrate support 114. Once seated, the substrate support 114 and the substrate 2 may be rotated about the rotation axis 155 (shown in FIG. 4), for example at a predetermined deposition operation rotational speed. The substrate 2 may be further be heated while seated on the substrate support 114, for example to a predetermined material layer deposition temperature using one or more external heater 197 (shown in FIG. 4) supported outside of the chamber body 186 and radiantly coupled to the substrate 2 by the chamber body 186. The interior 118 of the chamber body 186 may further be evacuated to a predetermined material layer deposition pressure, for example using the vacuum pump 153 (shown in FIG. 7) in cooperation with the chamber pressure sensor 147 (shown in FIG. 7) and the pressure control valve 149 (shown in FIG. 7). It is contemplated that one or more of the predetermined substrate support rotational speed, the predetermined material layer deposition temperature, and the predetermined material layer deposition pressure may be received by the system controller 110 as parameters within the aforementioned recipe string received from the factory host computer.

The deposition operation I may further include providing the first process fluid 10 to the first process fluid diverter valve 172 and the second process fluid 26 to the second process fluid diverter valve 176. The first process fluid diverter valve 172 may in turn communicate the first process fluid 10 to the chamber arrangement 104, the chamber body 186 in turn exposing the substrate 2 to the first process fluid 10 according to a deposition flow pattern 60, the material layer 4 thereby depositing according to the deposition flow pattern 60, and residual material layer precursor and/or reaction products 62 during the deposition operation I flowing to the exhaust source 106 through the exhaust conduit 116. It is also contemplated that the second process fluid diverter valve 176 may divert the second process fluid 26 to the bypass conduit 120 and therethrough to exhaust source 106 via the BPC 108 as the first process fluid diverter valve 172 communicates the first process fluid 10 to the chamber arrangement 104. Advantageously, diverting flow of the second process fluid 26 to the exhaust source 106 via the bypass conduit 120 enables stabilization of mass flow of the second process fluid 26 potentially required by flow control devices coupling the second process fluid source 168 to the second process fluid diverter valve 176, e.g., the second process fluid MFC device 174 (shown in FIG. 3), avoiding the need to stabilize flow of the second process fluid 26 during the etching operation II (shown in FIG. 9).

In certain examples of the present disclosure backpressure within the bypass conduit 120 may be controlled during the deposition operation I using a supply pressure measurement acquired using the second inject MFC device 182. In this respect it is contemplated that (a) the second inject MFC device 182 acquire a first process fluid supply pressure measurement 64; (b) the second inject MFC device 182 provide the first process fluid supply pressure measurement 64 to the system controller 110; and (c) the system controller 110 determine a deposition operation backpressure setpoint 66 using the first process fluid supply pressure measurement 64 and the deposition supply-to-bypass pressure differential value 48. In further respect, it is also contemplated that the system controller 110 in turn (d) provide the deposition operation backpressure setpoint 66 to the BPC 108, and that the BPC 108 (e) throttle backpressure within the bypass conduit 120 according to the deposition operation backpressure setpoint 66 received from the system controller 110, for example in a quasi-closed loop control regime wherein the BPC 108 throttles backpressure according to one or more deposition operation backpressure setpoint sequentially received from the BPC 108 during the deposition operation I. Advantageously, employment of a quasi-closed loop control regime enables the deposition operation I to be performed using a plurality of deposition operation supply-to-bypass pressure differential values, such as in deposition operations having two or more steps.

In accordance with certain examples, mass flow of the first process fluid 10 into the interior 118 of the chamber body 186 may be controlled according to total mass flow of the first process fluid 10 into the injection flange 184. In this respect it is contemplated that (a) the first inject MFC device 180 may acquire a deposition operation first inject MFC device flow rate measurement 68 and the second inject MFC device acquire a deposition operation second inject MFC device flow rate measurement 70; (b) the first inject MFC device 180 and the second inject MFC device 182 may provide the deposition operation first inject MFC device flow rate measurement 68 and the deposition operation second inject MFC device flow rate measurement 70 to the system controller 110; (c) the system controller 110 determine a deposition operation first inject MFC device flow rate setting 72 and a deposition operation second inject MFC device flow rate setting 74 using the both the deposition operation first inject MFC device flow rate measurement 68 and the deposition operation second inject MFC device flow rate measurement 70, respectively; and (d) the system controller 110 provide the deposition operation first inject MFC device flow rate setting 72 to the first inject MFC device 180 and the deposition operation second inject MFC device flow rate setting 74 to the second inject MFC device 182. As will be appreciated by those of skill in the art in view of the present disclosure, this enables accurate control of the deposition operation flow pattern 60.

It is contemplated that the system controller 110 may determine the deposition operation first inject MFC device flow rate setting 72 by (e) dividing the deposition operation first inject MFC device flow rate measurement 68 by a sum of the deposition operation first inject MFC device flow rate measurement 68 and the deposition operation second inject MFC device flow rate measurement 70; (f) comparing the quotient of (e) to the deposition operation first inject MFC device flow ratio target 52; and (g) sending the deposition operation first inject MFC device flow rate setting 72 to the first inject MFC device 180 when the quotient of (e) differs from the deposition operation first inject MFC device flow ratio target 52 by more than a predetermined differential value. It is also contemplated that system controller 110 may further determine the deposition operation second inject MFC device flow rate setting 74 by (h) dividing the deposition operation second inject MFC device flow rate measurement 70 by the sum of the deposition operation first inject MFC device flow rate measurement 68 and the deposition operation second inject MFC device flow rate measurement 70; (i) comparing the quotient of (h) to the deposition operation second inject MFC device flow ratio target 54; and (g) sending the deposition operation second inject MFC device flow rate setting 74 to the second inject MFC device 182 when the quotient of (h) differs from the deposition operation second inject MFC device flow ratio target 54 by more than the predetermined differential value. As will be appreciated by those of skill in the art in view of the present disclosure, the aforementioned operations may repeated iteratively during the deposition operation I. As will also be appreciated by those of skill in the art in view of the present disclosure, the aforementioned operations may be performed to update deposition MFC flow rate settings for each inject MFC device communicating the first process fluid to the chamber body 186, for example in chamber arrangements including four (4) first inject MFC devices 180 and a singular (e.g., one and only one) second inject MFC device 182.

The deposition operation I may further include providing the first process fluid 10 to the first process fluid diverter valve 172 and the second process fluid 26 to the second process fluid diverter valve 176. The first process fluid diverter valve 172 may in turn communicate the first process fluid 10 to the chamber arrangement 104, the chamber body 186 in turn exposing the substrate 2 to the first process fluid 10 according to the deposition flow pattern 60, the material layer 4 thereby depositing according to the deposition flow pattern 60, and residual material layer precursor and/or reaction products 62 during the deposition operation I flowing to the exhaust source 106 through the exhaust conduit 116. It is also contemplated that the second process fluid diverter valve 176 may divert the second process fluid 26 to the bypass conduit 120 and therethrough to exhaust source 106 via the BPC 108 as the first process fluid diverter valve 172 communicates the first process fluid 10 to the chamber arrangement 104. Advantageously, diverting flow of the second process fluid 26 to the exhaust source 106 via the bypass conduit 120 enables stabilization of mass flow of the second process fluid 26 potentially required by flow control devices coupling the second process fluid source 168 to the second process fluid diverter valve 176, e.g., the second process fluid MFC device 174 (shown in FIG. 3), avoiding the need to stabilize flow of the second process fluid 26 during the etching operation II.

As shown in FIG. 9, the etching operation II may be accomplished by switching flow of the second process fluid 26 from the bypass conduit 120 to the chamber arrangement 104. In this respect flow of the first process fluid 10 may cease and the first process fluid diverter valve 172 be actuated such that the first process fluid diverter valve 172 fluidly separates the first process fluid source 166 from the supply conduit 112. The second process fluid diverter valve 176 may further be actuated such that second process fluid diverter valve 176 fluidly couples the second process fluid source 168 with the supply conduit 112 and therethrough to the chamber arrangement 104 via the first inject MFC device 180 and the second inject MFC device 182. It is contemplated that the first inject MFC device 180 and the second inject MFC device 182 thereafter cooperate to introduce the second process fluid 26 into the interior 118 of the chamber body 186, that the chamber body 186 expose the substrate 2 and the material layer 4 deposited thereon according to an etch flow pattern 76, and that residual second process fluid and/or etch products 78 issued by the chamber body 186 are communicated to the exhaust source 106 by the exhaust conduit 116.

Backpressure within the bypass conduit 120 may also be controlled during the etch operation II using a supply pressure measurement acquired using the second inject MFC device 182. In this respect it is contemplated that (a) the second inject MFC device 182 acquire a second process fluid supply pressure measurement 80 as the second process fluid 26 flows to the chamber body 186; (b) the second inject MFC device 182 provide the second process fluid supply pressure measurement 80 to the system controller 110; and (c) the system controller 110 in turn determine an etch operation backpressure setpoint 82 using the second process fluid supply pressure measurement 80 and the etch supply-to-bypass pressure differential value 50 (shown in FIG. 1). In further respect, it is further contemplated that the system controller 110 (d) provide the etch operation backpressure setpoint 82 to the BPC 108, and that the BPC 108 (e) control backpressure within the bypass conduit 120 according to the etch operation backpressure setpoint 82 received from the system controller 110. In certain examples, backpressure may be controlled in a quasi-closed loop control regime during the etch operation II. In this respect the BPC 108 may throttle backpressure within the bypass conduit 120 according to two or etch operation backpressure setpoint 82 sequentially received from the BPC 108 responsive to changes in pressure within the supply conduit 112 during the etch operation II.

In accordance with certain examples, mass flow of the second process fluid 26 into the interior 118 of the chamber body 186 may be controlled according to total mass flow of the second process fluid 26 into the injection flange 184 from each of the plurality of inject MFC devices fluidly coupling the inject header 178 to the injection flange 184. In this respect it is contemplated that (a) the first inject MFC device 180 acquire an etch operation first inject MFC device flow rate measurement 84 and the second inject MFC device acquire an etch operation second inject MFC device flow rate measurement 86; (b) the first inject MFC device 180 and the second inject MFC device 182 provide the etch operation first inject MFC device flow rate measurement 84 and the etch operation second inject MFC device flow rate measurement 86 to the system controller 110; (c) the system controller 110 determine an etch operation first inject MFC device flow rate setting 88 and an etch operation second inject MFC device flow rate setting 90 using the both the etch operation first inject MFC device flow rate measurement 84 and the etch operation second inject MFC device flow rate measurement 86, respectively; and (d) the system controller 110 provide the etch operation first inject MFC device flow rate setting 88 to the first inject MFC device 180 and the etch operation second inject MFC device flow rate setting 90 to the second inject MFC device 182.

In certain examples of the present disclosure the system controller 110 may determine the etch operation first inject MFC device flow rate setting 88 by (e) dividing the etch operation first inject MFC device flow rate measurement 84 by a sum of the etch operation first inject MFC device flow rate measurement 84 and the etch operation second inject MFC device flow rate measurement 86; (f) comparing the quotient of (e) to the etch operation first inject MFC device flow ratio target 56 (shown in FIG, 8); and (g) providing an updated etch operation first inject MFC device flow rate setting 72 to the first inject MFC device 180 when the quotient of (e) differs from the etch operation first inject MFC device flow ratio target 56 by more than a predetermined differential value. It is also contemplated that system controller 110 further determine the etch operation first inject MFC device flow rate setting 88 by (h) dividing the etch operation second inject MFC device flow rate measurement 86 by the sum of the etch operation first inject MFC device flow rate measurement 84 and the etch operation second inject MFC device flow rate measurement 86; (i) comparing the quotient of (h) to the etch operation second inject MFC device flow ratio target 58 (shown in FIG. 8); and (g) sending an updated etch operation second inject MFC device flow rate setting 90 to the second inject MFC device 182 when the quotient of (h) differs from the etch operation second inject MFC device flow ratio target 58 by more than the predetermined differential value. As will be appreciated by those of skill in the art in view of the present disclosure, the aforementioned operations may repeated iteratively during the etch operation II. As will also be appreciated by those of skill in the art in view of the present disclosure, this enables accurate control of the etch operation flow pattern 76.

In the illustrated example the first process fluid 10 and the second process fluid 26 are introduced into the chamber body 186 through a common (e.g., singular) MFC arrangement 157. It is contemplated that the chamber arrangement 104 may have more than one MFC arrangement in certain examples of the present disclosure, for example a deposition MFC arrangement and an etch MFC arrangement. In such examples the first process fluid source 166 may be coupled to the chamber body 186 by the first process fluid diverter valve 172 and the deposition inject MFC arrangement and the second process fluid source 168 may be coupled to the chamber body 186 by the second process fluid diverter valve 176 and the etch MFC arrangement. The deposition inject MFC arrangement may include the first inject MFC device 180 and the second inject MFC device 182 and communicate the first process fluid 10 to the chamber body 186, and the etch MFC arrangement additionally include similarly arranged MFC devices. As will also be appreciated by those of skill in the art in view of the present disclosure, the aforementioned operations may be performed to update etch MFC flow rate settings for each inject MFC device communicating the first process fluid to the chamber body 186, for example in chamber arrangements including four (4) first inject MFC devices 180 and a singular (e.g., one and only one) second inject MFC device 182 fluidly coupling the inject header 178 to the injection flange 184.

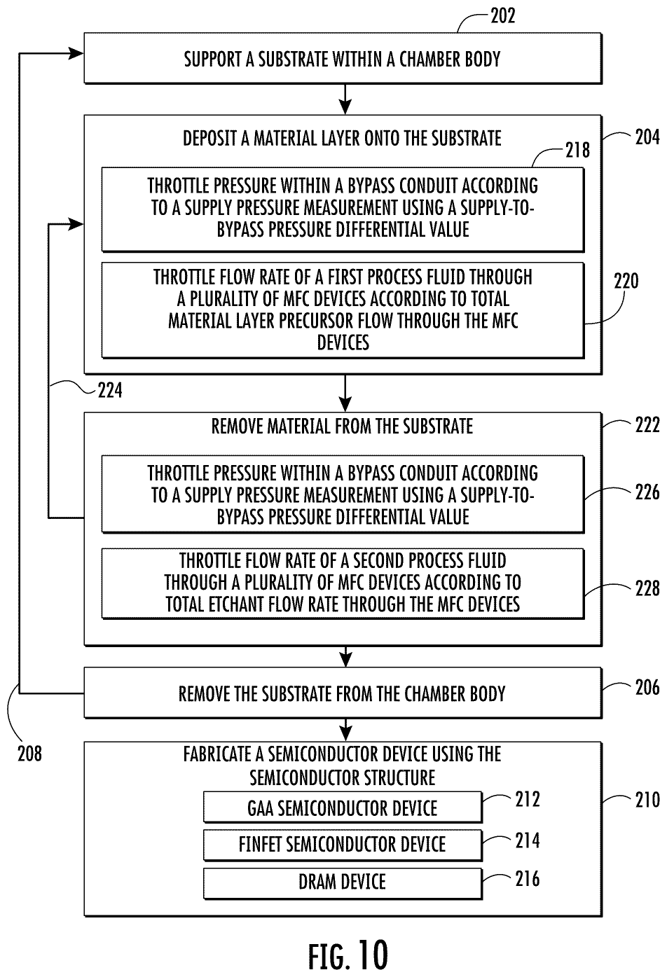

With reference to FIGS. 10-13, the method 200 of forming a semiconductor structure, e.g., the semiconductor structure 92 (shown in FIG. 9), is shown. Referring to FIG. 10, forming 200 the semiconductor structure may include supporting a substrate within a chamber body, e.g., the substrate 2 (shown in FIG. 1) within the chamber body 186 (shown in FIG. 4), as shown with box 202. Forming 200 the semiconductor structure may also include depositing a material layer onto the substrate, e.g., depositing the material layer 4 (shown in FIG. 8) onto the substrate, as shown with box 204. Forming 200 the semiconductor structure may further include removing the substrate from the chamber body for further processing, as appropriate for the intended use of the semiconductor structure, and thereafter seating another substrate within the chamber body for forming a further semiconductor thereon, as shown with box 206 and arrow 208. In certain examples of the present disclosure a semiconductor device may be fabricated using the semiconductor structure formed on the substrate, as shown with box 210. In this respect it is contemplated that a semiconductor device may be fabricated using the semiconductor structure, such as logic device having a gate-all-around or a finned architecture, as shown with box 212 and box 214. In further respect, it is also contemplated that a memory-type semiconductor device may be formed using the semiconductor structure, such as a dynamic random access memory device having a three-dimensional architecture, as shown with box 216.

In certain examples, depositing 204 the material layer may include throttling backpressure within a bypass conduit coupled fluidly in parallel with the chamber body, e.g., backpressure within the bypass conduit 120 (shown in FIG. 1), as shown with box 218. Depositing 204 the material layer may also include throttling individual flow rates of a first process fluid introduced into the chamber body through inject MFC devices of an MFC arrangement coupled to the chamber body, e.g., the first process fluid 10 introduced through both the first inject MFC device 180 (shown in FIG. 4) and the second inject MFC device 182 (shown in FIG. 4) of the MFC arrangement 157 (shown in FIG. 4) into the chamber body 186 during the deposition operation I, as shown with box 220. In this respect it is contemplated that that flow rate of the first process fluid 10 may be throttled through the plurality of MFC devices of the MFC arrangement 157 according to total flow rate of the first process fluid 10 through the plurality of MFC devices of the MFC arrangement 157, as also shown with box 220.

In accordance with certain examples, forming 200 the semiconductor structure may include removing material from the substrate and/or material layer using a second process fluid, e.g., removing the material 94 (shown in FIG. 9) using the second process fluid 26 (shown in FIG. 9), as shown with box 222. Deposition and subsequent removal of material from the substrate and/or the material layer may one of plurality of deposition and removal cycles, as shown with arrow 224. In such examples removing 206 material from the substrate and/or the material layer may include throttling backpressure within a bypass conduit coupled fluidly in parallel with the chamber body, e.g., within the bypass conduit 120 (shown in FIG. 1), as shown with box 226. In such examples removing 206 material from the substrate and/or the material layer may also include throttling individual flow rates of the second process fluid introduced into the chamber body through inject MFC devices of an MFC arrangement coupled to the chamber body, e.g., introduced through the first inject MFC device 180 (shown in FIG. 4) and the second inject MFC device 182 (shown in FIG. 4) of the MFC arrangement 157 (shown in FIG. 4) during the etch operation II (shown in FIG. 9), according to total flow rate of the second process fluid through the MFC arrangement, as shown with box 228. In this respect it is contemplated that that flow rate of the second process fluid may be throttled through the plurality of MFC devices according to total flow rate of the second process fluid through the plurality of MFC devices, as also shown with box 228.

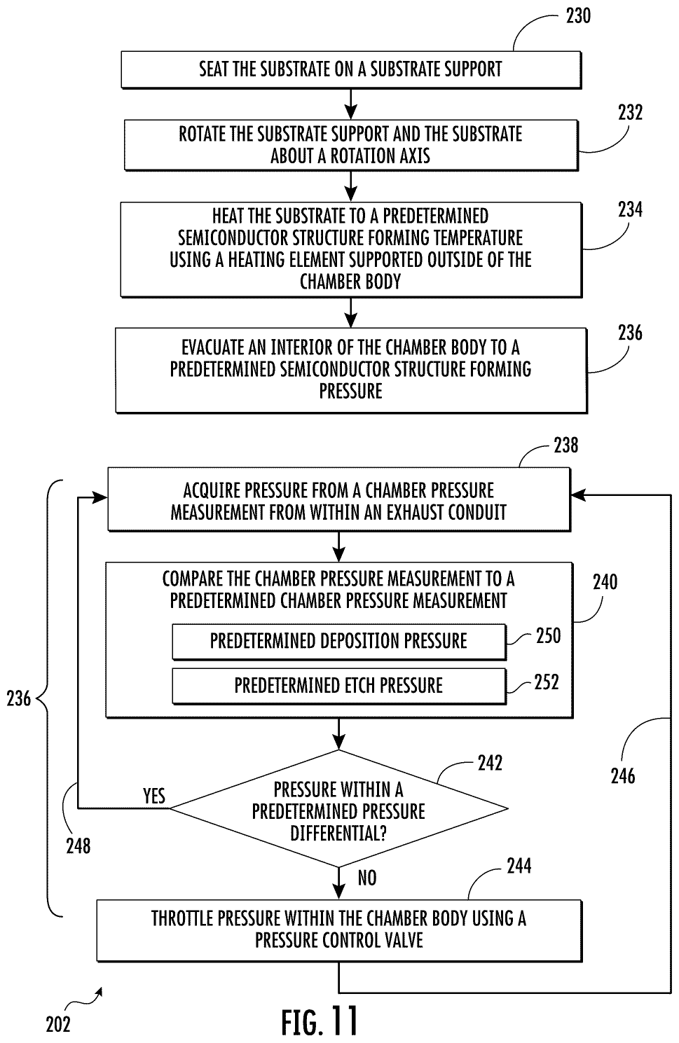

Referring to FIG. 11, supporting 202 the substrate within the chamber body may include seating the substrate on a substrate support, e.g., the substrate support 114 (shown in FIG. 1), as shown with box 230. Supporting 202 the substrate within the chamber body may include rotating the substrate support and the substrate about a rotation axis, e.g., the rotation axis 195 (shown in FIG. 4), as shown with box 232. Supporting 202 the substrate within the chamber body may include heating the substrate using a heater element arranged outside of the chamber body, e.g., the one or more heater element 197 (shown in FIG. 4), as shown with box 234. Supporting 202 the substrate within chamber body may further include evacuating an interior of the chamber body to a predetermined pressure using an exhaust source, e.g., the exhaust source 106 (shown in FIG. 1), as shown with box 236.

Evacuating 236 the chamber body may include acquiring a chamber pressure measurement using a chamber pressure sensor, e.g., the chamber pressure measurement 44 (shown in FIG.) using the chamber pressure sensor 147 (shown in FIG. 7), as shown with box 238. Evacuating 236 the chamber body may further include comparing the chamber pressure measurement to a predetermined chamber pressure value, as shown with box 240. Pressure within the chamber body may be throttled when the chamber pressure measurement differs from a predetermined chamber pressure value by more than a predetermined chamber pressure differential, as shown with box 242 and box 244, the aforementioned operations thereafter repeated, as shown with arrow 246. It is also contemplated no pressure throttling may occur when the difference between the chamber pressure measurement and the predetermined chamber pressure value is less than the predetermined chamber pressure differential value, as shown with arrow 248. In certain examples the chamber pressure measurement and the predetermined chamber pressure value may be a deposition operation chamber pressure measurement and a predetermined deposition operation chamber pressure value, respectively, as shown with box 250. In accordance with certain examples, the chamber pressure measurement and the predetermined chamber value may be an etch operation chamber pressure measurement and a predetermined etch operation chamber pressure value, as shown with box 252. Chamber pressure throttling may be accomplished using a pressure control valve, e.g., the pressure control valve 149 (shown in FIG. 7), as also shown with box 244.

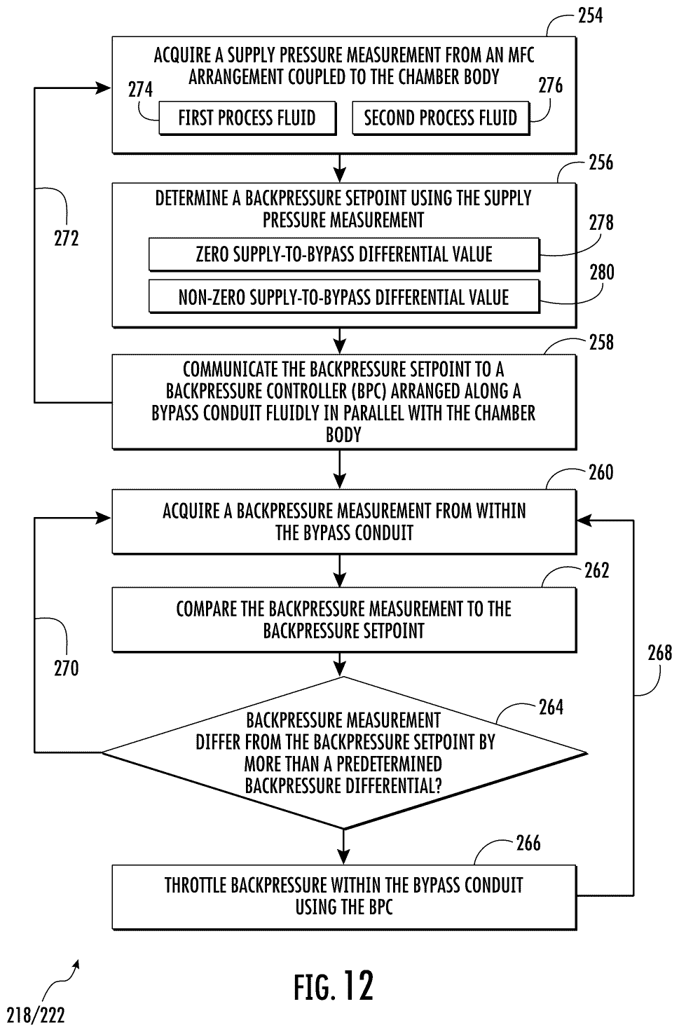

Referring to FIG. 12, throttling 218 pressure within the bypass conduit during deposition of the material layer onto the substrate and/or during removal of material from the substrate and/or material layer may include acquiring a supply pressure measurement from an MFC arrangement coupled to the chamber body, e.g., from the second inject MFC device 182, as shown with box 254. A deposition backpressure setpoint may be determined using the supply pressure measurement and a deposition operation supply-to-bypass differential value, for example by adding the deposition supply-to-bypass differential value to the supply pressure measurement, as shown with box 256. Backpressure within the bypass conduit may be controlled using the deposition operation backpressure setpoint, for example by communicating the backpressure setpoint to a BPC arranged along the bypass conduit, e.g., the BPC 108 (shown in FIG. 1), as shown box 258. In this respect it is contemplated that a backpressure measurement may be acquired from within the bypass conduit and the backpressure measurement compared to the deposition backpressure setpoint, for example using the BPC, as shown with box 260 and box 262. When the backpressure differs from the deposition backpressure setpoint by more than a predetermined deposition backpressure differential backpressure within the bypass conduit may be throttled, as shown with box 264 and box 266, and aforementioned comparison repeated within the BPC, as shown with arrow 268. When the backpressure measurement differs from the deposition backpressure setpoint by less than the predetermined deposition backpressure differential no throttling may occur, and a further backpressure measurement acquired and the aforementioned comparison repeated, as shown with arrow 270. Notably, further backpressure setpoints may be determined and provided to the BPC during processing, pressure differential between the backpressure within the bypass conduit and the supply conduit notwithstanding change of pressure within the supply conduit, as shown with arrow 272.

In certain examples, the supply pressure measurement may be acquired as the first process fluid traverses the MFC arrangement during the deposition operation I (shown in FIG. 8), for example a silicon-containing material layer precursor, as shown with box 274. In accordance with certain examples, the backpressure measurement may be acquired as the second process fluid traverses the bypass conduit, such as an etchant, as also shown with box 274. It is also contemplated that the supply pressure measurement may be acquired as the second process fluid traverses the MFC arrangement during the etch operation II (shown in FIG. 9), for example as the etchant traverses the MFC arrangement, as shown with box 276. In accordance with certain examples, the backpressure measurement may be acquired as the first process fluid traverses the bypass conduit, for example as the material layer precursor traverses the bypass conduit, as also shown with box 276. It is further contemplated that the supply-to-bypass pressure differential value may zero or a non-zero value, for example in either (or both) the deposition operation and the etch operation, as shown with box 278 and box 280.

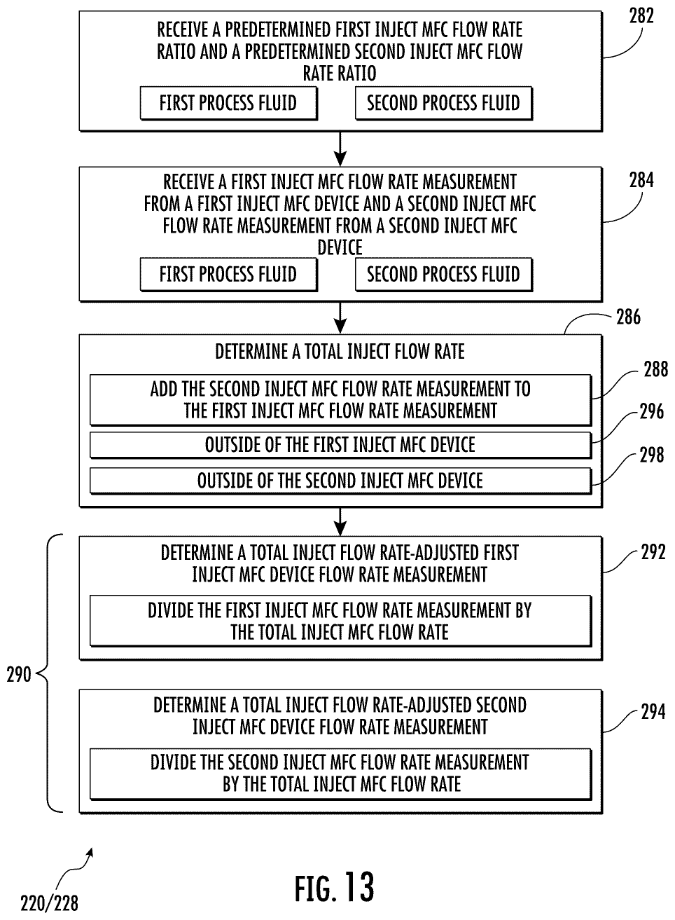

Referring to FIG. 13, throttling 220 flow rate of the first process fluid and/or throttling of the second process fluid 228 into the chamber body through the plurality of inject MFC devices according to total flow rate may include receiving a predetermined first inject MFC flow ratio and a predetermined second MFC flow ratio, for example at the system controller 110 (shown in FIG. 1), as shown with box 282. A first inject MFC flow rate measurement and a second inject MFC flow rate measurement may also be received from inject MFC devices of an MFC arrangement, e.g., the deposition operation first inject MFC device flow rate measurement 68 (shown in FIG. 8) from the first inject MFC device 180 (shown in FIG. 4) and the deposition operation second inject MFC device flow rate measurement 70 (shown in FIG. 8) from the second inject MFC device 182 (shown in FIG. 4), as shown with box 284.

A total inject flow rate for the MFC arrangement may be calculated using the plurality of inject MFC flow rate measurements, for example by adding the second inject MFC flow rate measurement to the first inject MFC flow rate measurement, as shown box 286 and box 288. It is contemplated that a total inject flow rate-adjusted inject MFC device flow rate ratio may be determined using the total inject flow rate for the first inject MFC device and the second inject MFC device, as shown with bracket 290. In this respect it is contemplated that a total inject flow rate-adjusted first inject MFC flow rate ratio for the first inject MFC device be determined by dividing the first inject MFC device flow rate measurement by the total flow rate, as shown with box 292, and a total inject flow rate-adjusted second inject MFC device flow rate ratio for the second inject MFC device be determined by dividing the second inject MFC device flow rate measurement by the total flow rate, as shown with box 294. Determining 282 the total inject flow rate, determining 292 the total inject flow-rate-adjusted first inject MFC device flow rate measurement, and determining 294 the total inject flow-rate adjusted second MFC device flow rate measurement may be determined outside of the MFC arrangement, e.g., outside of the first inject MFC device and the second inject MFC device, in a quasi-closed loop regime, as shown with box 296 and box 298.

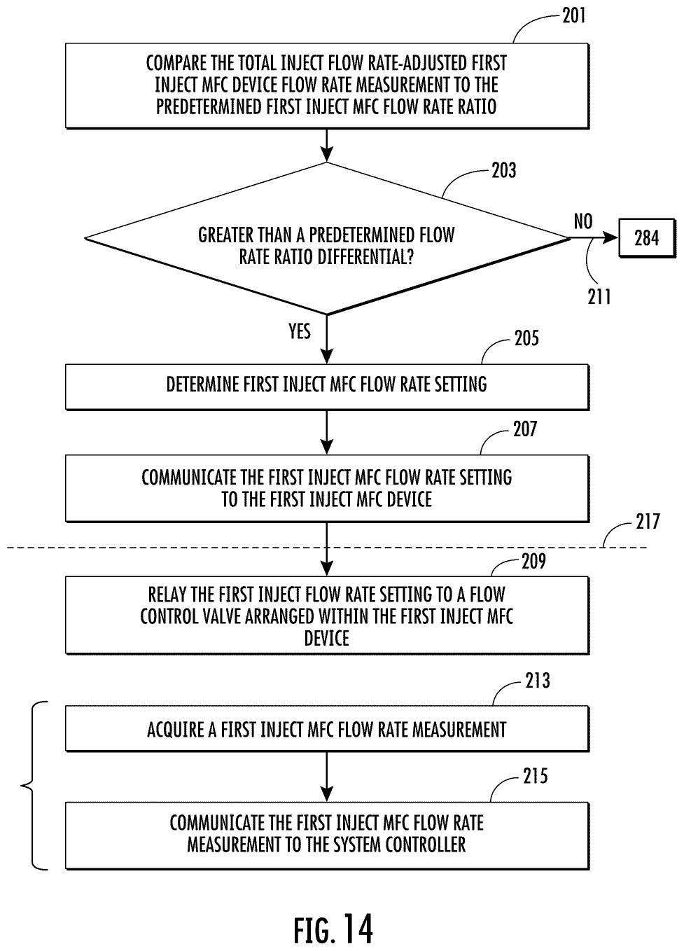

Referring to FIG. 14, it is contemplated that the total inject flow rate-adjusted first inject MFC device flow rate measurement may be compared to the predetermined first inject MFC flow rate ratio, as shown with box 201. When the total inject flow rate-adjusted first inject MFC device flow rate measurement differs from the predetermined first inject MFC flow rate ratio by more than a predetermined flow rate ratio differential, a first inject MFC flow rate setpoint may be determined, as shown with box 203 and box 205, and flow rate through the first inject MFC device throttled according to the first inject MFC flow rate setting by communicating the first inject MFC flow rate setting to the first inject MFC device and relaying the first inject MFC flow rate setting therein to a flow control valve arranged therein, as shown with box 207 and box 209. When the total inject flow rate-adjusted first inject MFC device flow rate measurement differs from the predetermined first inject MFC flow rate ratio by less that the predetermined flow rate differential no first inject MFC flow setting may be determined and monitoring on a total inject flow rate-adjusted basis continue, as shown with arrow 211. In either event it is contemplated that the first inject MFC device acquire one or more additional first inject MFC device flow rate measurements and communicate the one or more additional first inject MFC device flow rate measurement to the system controller, as shown with box 213 and box 215.

It is contemplated that the comparing 201 may be accomplished outside of the first inject MFC device (e.g., remotely), for example on the system controller, the first inject MFC flow rate measurement and the determined first inject MFC device flow rate setting being communicated to the first inject MFC device by the system controller. In this respect the first inject MFC device flow rate setting may be relayed therein to a flow control valve arranged within the first inject MFC device, as shown with line 217, such as in a distributed computing regime. As will be appreciated by those of skill in the art in view of the present disclosure, the comparing 201 may alternatively be accomplished within the first inject MFC device (e.g., locally), the system controller communicating the total inject flow rate to the first inject MFC device such that a first inject MFC device controller arranged within the first inject MFC device may perform the comparing 201 in a more limited distributed computing regime.

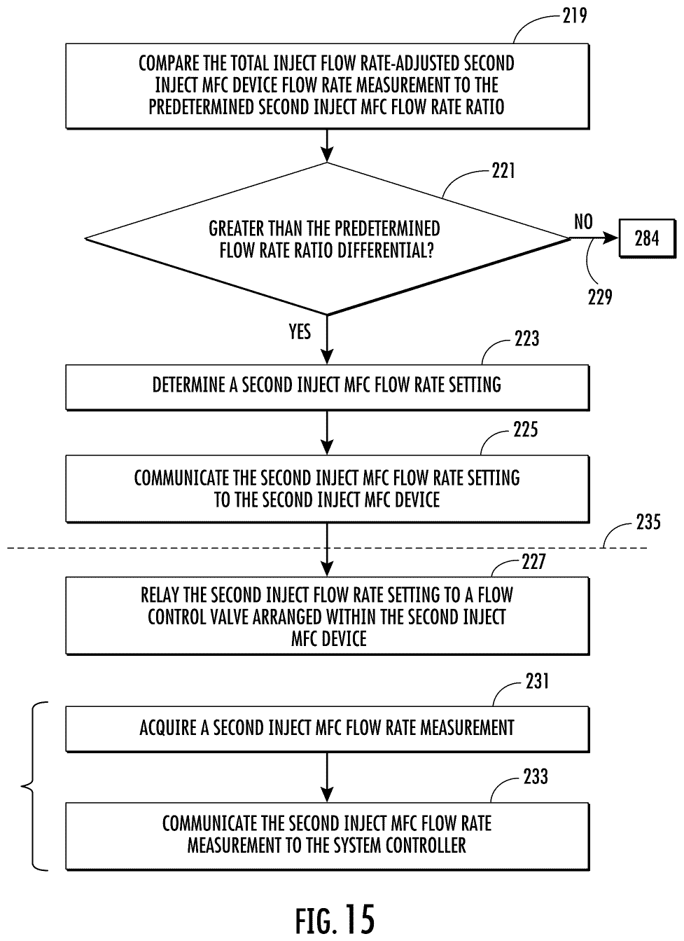

Referring to FIG. 15, it is also contemplated that the total inject flow rate-adjusted second inject MFC device flow rate measurement may be compared to the predetermined second inject MFC flow rate ratio, as shown with box 219. When the total inject flow rate-adjusted second inject MFC device flow rate measurement differs from the predetermined second inject MFC flow rate ratio by more than the predetermined flow rate ratio differential, a second inject MFC flow rate setpoint may be determined, as shown with box 221 and box 223, and flow rate through the second inject MFC device may be throttled according to the second inject MFC flow rate setting by communicating the second inject MFC flow rate setting to the second inject MFC device and relaying the second inject MFC flow rate setting therein to a flow control valve arranged within the second inject MFC device, as shown with box 225 and box 227. When the total inject flow rate-adjusted second inject MFC device flow rate measurement differs from the predetermined second inject MFC flow rate ratio by less that the predetermined flow rate differential no second inject MFC flow setting may be determined, and monitoring on flow rate through the second inject MFC device on a total inject flow rate-adjusted basis may continue, as shown with arrow 229. In either event it is also contemplated that the second inject MFC device acquire one or more additional second inject MFC device flow rate measurements and communicate the one or more additional second inject MFC device flow rate measurement to the system controller, as shown with box 231 and box 233.

As with the first inject MFC device, it is further contemplated that the comparing 219 may be accomplished outside of the second inject MFC device (e.g., remotely), for example on the system controller. In this respect the second inject MFC flow rate measurement and the determined second inject MFC device flow rate setting may be communicated to the second inject MFC device by the system controller, the second inject MFC device flow rate setting therein being relayed to a flow control valve arranged within the second inject MFC device in a distributed computing regime, as shown with line 235. As will be appreciated by those of skill in the art in view of the present disclosure, the comparing 219 may alternatively be accomplished within the second inject MFC device (e.g., locally), the system controller communicating the total inject flow rate to the second inject MFC device such that a second inject MFC device controller arranged within the second inject MFC device may perform the comparing 219 in a relatively limited distributed computing regime.

As will be appreciated by those of skill in the art in view of the present disclosure, the aforementioned operations may be performed to control flow rate on a total inject flow rate-adjusted basis may be performed for each of the MFC devices of the MFC arrangement, for example for each inject MFC device of the MFC arrangement 157 (shown in FIG. 4). As will also be appreciated by those of skill in the art in view of the present disclosure, the aforementioned operations may also be performed during either (or both) deposition and material removal operations, e.g., during the deposition operation I (shown in FIG. 8) and the etch operation II (shown in FIG. 9), as well as using either a common MFC arrangement or dedicated deposition and etch MC arrangements.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A chamber arrangement, comprising:
a chamber body;
a mass flow controller (MFC) arrangement coupled to the chamber body, comprising:
a first inject MFC device coupled to the chamber body; and
a second inject MFC device coupled to the chamber body and arranged fluidly in parallel with the first inject MFC device; and
a bypass conduit with a backflow controller (BPC) arranged fluidly in parallel with the chamber body and the MFC arrangement, wherein one of the first inject MFC device and the second inject MFC device is operatively coupled to the BPC.

2. The chamber arrangement of claim 1, wherein only one of the first inject MFC device and the second inject MFC device includes a pressure sensor.

3. The chamber arrangement as recited in claim 1, further comprising:
an exhaust conduit connected to the chamber body;
a supply conduit connected to the MFC arrangement; and
where the MFC arrangement and the chamber body fluidly couple the supply conduit in series with the exhaust conduit.

4. The chamber arrangement as recited in claim 3, further comprising:
a process fluid diverter valve arranged along the supply conduit;
a joint or union arranged along the exhaust conduit; and
wherein the bypass conduit couples the joint or union to the process fluid diverter valve.

5. The chamber arrangement of claim 4, wherein the process fluid diverter valve is a first process fluid diverter valve, the chamber arrangement further comprising:
a second process fluid diverter valve coupled to the supply conduit and therethrough to the MFC arrangement;
a first process fluid source including a silicon-containing material layer precursor source coupled to the first process fluid diverter valve; and
a second process fluid source including an etchant coupled to the second process fluid diverter valve.

6. The chamber arrangement of claim 3, further comprising:
a chamber pressure sensor arranged along the exhaust conduit; and
a pressure control valve arranged along the exhaust conduit and coupled to the chamber body by the chamber pressure sensor.

7. The chamber arrangement of claim 1, wherein the first inject MFC device includes:
a housing supporting an inlet port, an outlet port, and a signal port;
a flow rate sensor arranged within the housing and coupled to the inlet port;
a flow control valve arranged within the housing and coupling the flow rate sensor to the outlet port; and
a first inject MFC local controller arranged within the housing and coupled to the signal port, wherein the first inject MFC local controller is configured to communicate a first inject MFC flow rate measurement to a system controller through the signal port and receive a first inject MFC flow rate setting through the signal port.

8. The chamber arrangement of claim 7, further comprising at least one of a jumper lead coupling the flow rate sensor to the signal port and a jumper module recorded on a memory included in the first inject MFC local controller to relay the first inject MFC flow rate measurement to the system controller through the signal port and receive the first inject MFC flow rate setting from the system controller through the signal port.

9. The chamber arrangement of claim 1, wherein the second inject MFC device includes:
a housing supporting an inlet port, an outlet port, and a signal port;
a pressure sensor arranged within the housing and coupled to the inlet port;
a flow rate sensor arranged within the housing and coupled to the pressure sensor;
a flow control valve arranged within the housing and coupling the flow rate sensor to the outlet port; and
a second inject MFC local controller arranged within the housing and coupled to the signal port, wherein the second inject MFC local controller is configured to communicate a supply pressure measurement and a first inject MFC flow rate measurement to a system controller through the signal port and receive a second inject MFC flow rate setting through the signal port.

10. The chamber arrangement of claim 9, further comprising at least one of a jumper lead coupling the flow rate sensor to the signal port and a jumper module recorded on a memory included in the second inject MFC local controller to relay the supply pressure measurement and a second inject MFC device flow rate measurement therethrough to the system controller and receive therethrough the second inject MFC flow rate setting from the system controller.

11. The chamber arrangement of claim 1, wherein the BPC comprises:
a housing supporting an inlet port, an outlet port, and a signal port;
a capacitive manometer arranged within the housing and coupled to the inlet port;
a flow control valve arranged within the housing and coupling the capacitive manometer to the outlet port;
a BPC local controller arranged within the housing a coupled to the signal port and responsive to instructions recorded on a memory to:
receive a backpressure setpoint from a system controller through the signal port;
receive a backpressure measurement from the capacitive manometer;
compare the backpressure measurement to the backpressure setpoint; and
throttle backpressure within the bypass conduit when the backpressure measurement is greater than the backpressure setpoint by a predetermined backpressure differential value.

12. A semiconductor processing system, comprising:
a chamber arrangement as recited in claim 1, wherein the MFC arrangement fluidly couples a supply conduit to an exhaust conduit;
a process fluid diverter valve arranged along the supply conduit and a joint or union arranged along the exhaust conduit, wherein the bypass conduit couples the process fluid diverter valve to the joint or union; and
a system controller operatively coupling the MFC arrangement to the BPC, wherein the system controller is responsive to instructions recorded on a memory to:
receive a supply pressure measurement from the MFC arrangement acquired by one of the first inject MFC device and the second inject MFC device;
receive a supply-to-bypass differential value;
determine a backpressure setpoint using the supply pressure measurement and the supply-to-bypass differential value; and
communicate the backpressure setpoint to the BPC to throttle backpressure within the bypass conduit using the supply pressure measurement.

13. The semiconductor processing system of claim 12, wherein determining the backpressure setpoint includes adding the supply-to-bypass differential value to the supply pressure measurement.

14. The semiconductor processing system of claim 13, wherein the supply-to-bypass differential value is zero.

15. The semiconductor processing system of claim 13, wherein the supply-to-bypass differential value is a non-zero value.

16. The semiconductor processing system of claim 12, wherein the instructions recorded on the memory further cause the system controller to:
acquire a first inject MFC device flow rate measurement of a first process fluid as the first process fluid traverses the first inject MFC device;
acquire a second inject MFC device flow rate measurement of the first process fluid as the first process fluid traverses the second inject MFC device;
determine a first inject MFC device setpoint using the first inject MFC device flow rate measurement and the second inject MFC device flow rate measurement;
determine a second inject MFC device setpoint using the first inject MFC device flow rate measurement and the second inject MFC device flow rate measurement; and
communicate the first inject MFC device setpoint to the first inject MFC device and the second inject MFC device setpoint to the second MFC device.

17. A method of forming a semiconductor device structure, comprising:
at a chamber arrangement including a chamber body; a mass flow controller (MFC) arrangement connected to the chamber body including a first inject MFC device and a second inject MFC device, the first inject MFC device coupled to the chamber body and the second inject MFC device coupled to the chamber body and arranged fluidly in parallel with the first inject MFC device; and a bypass conduit with backflow controller (BPC) arranged therealong fluidly in parallel with the chamber body and the MFC arrangement, one of the first inject MFC device and the second inject MFC device operatively coupled to the BPC;
seating a substrate within the chamber body;
flowing a first process fluid into the chamber body using the first inject MFC device and the second inject MFC device;
forming a semiconductor structure on the substrate using the first process fluid; and
throttling backpressure within a bypass conduit arranged fluidly in parallel with the MFC arrangement and the chamber arrangement with the BPC using a supply pressure measurement acquired by the one of the first inject MFC device and the second inject MFC device.

18. The method of claim 17, wherein the first process fluid includes a silicon-containing material layer precursor, wherein a second process fluid includes an etchant, the method further comprising:
ceasing flow of the first process fluid to the chamber arrangement;
switching flow of the second process fluid from the bypass conduit to the chamber arrangement; and
removing a portion of a silicon-containing material layer deposited onto the substrate using the first process fluid using the second process fluid.

19. The method of claim 17, wherein the first inject MFC device does not include a pressure sensor, and wherein throttling pressure within the bypass conduit comprises:
acquiring the supply pressure measurement using the second inject MFC device;
determining a backpressure setpoint using the supply pressure measurement and a supply-to-pressure differential value; and
receiving the backpressure setpoint at the BPC and throttling backpressure within the bypass conduit according the backpressure setpoint during deposition of a material layer onto the substrate.

20. The method of claim 17, wherein flowing the first process fluid into the chamber arrangement comprises:
acquiring a first inject MFC device flow rate measurement of the first process fluid as the first process fluid traverses the first inject MFC device;
acquiring a second inject MFC device flow rate measurement of the first process fluid as the first process fluid traverses the second inject MFC device;
determining a first inject MFC device setpoint using the first inject MFC device flow rate measurement and the second inject MFC device flow rate measurement;
determining a second inject MFC device setpoint using the first inject MFC device flow rate measurement and the second inject MFC device flow rate measurement; and
communicating the first inject MFC device setpoint to the first inject MFC device and the second inject MFC device setpoint to the second inject MFC device.
